(19) United States
(12) Patent Application Publication
(10) Pub. No.: US 2026/0096149 A1
(43) Pub. Date: Apr. 2, 2026

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Po-Kuei LIN, Taichung City (TW); Yi-Juei LEE, Hsinchu City (TW); Wen-Che TSAI, Hsinchu City (TW); Pin-Chun SHEN, Changhua County (TW); Fu-Hsiang SU, Zhubei city (TW); Kao-Ting LAI, Hsinchu City (TW)

(21) Appl. No.: 18/904,244

(22) Filed: Oct. 2, 2024

(51) Int. Cl. H01L 29/423; H01L 21/8234; H01L 27/088; H01L 29/06; H01L 29/66; H01L 29/775; H01L 29/786; H10B 10/00

(52) U.S. Cl. CPC H10D 30/6735; H10B 10/12; H10D 30/014; H10D 30/43; H10D 30/6757; H10D 62/121; H10D 64/017; H10D 64/018; H10D 84/0128; H10D 84/013; H10D 84/038; H10D 84/83

(57) ABSTRACT

A method for manufacturing a semiconductor structure includes forming fins over a substrate. Each of the fins includes first and second semiconductor layers alternating stacked, and a third semiconductor layer under the first and second semiconductor layers. The method further includes forming a dummy gate structure over the fins, forming source/drain trenches on opposite sides of the dummy gate structures, removing the third semiconductor layers, forming first dielectric layers under the first and second semiconductor layers and in the source/drain trenches, replacing the first semiconductor layers with second dielectric layers, forming source/drain features in the source/drain trenches and on opposite sides of the dummy gate structure, forming air gaps between the source/drain features and the first dielectric layers, and replacing the dummy gate structure and the second dielectric layers with a gate structure wrapping around the second semiconductor layers and over the first dielectric layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins.

However, as GAA devices continue to be scaled down, conventional methods for manufacturing GAA devices may experience challenges. Accordingly, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, and 2C illustrate circuit schematics of various STD cells that can be implemented in the logic region of the IC chip of FIG. 1 in accordance with some embodiments of the present disclosure.

FIGS. 3 and 4 illustrate circuit schematics of a static random access memory (SRAM) cell that can be implemented in the memory region of the IC chip of FIG. 1, in accordance with some embodiments of the present disclosure.

FIG. 5 is a perspective view of a workpiece at a fabrication stage, in accordance with some embodiments of the present disclosure.

FIGS. 6A, 7A, 8A, 9A, 10A, 11A, 12A, 13A, 14A, and 15A are X-Z cross-sectional views of the workpiece at various fabrication stages along a line A-A′ or a line B-B′ of FIG. 5, in accordance with some embodiments of the present disclosure.

FIGS. 16A, 17A, 18A, and 19A are X-Z cross-sectional views of the workpiece at various fabrication stages along the line A-A′ of FIG. 5, in accordance with some embodiments of the present disclosure.

FIGS. 16B, 17B, 18B, and 19B are X-Z cross-sectional views of the workpiece at various fabrication stages along the line B-B′ of FIG. 5, in accordance with some embodiments of the present disclosure.

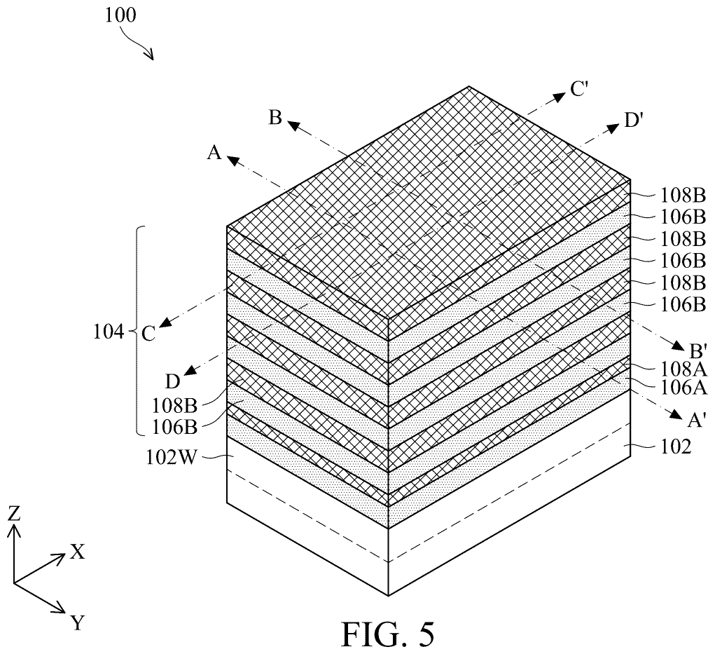

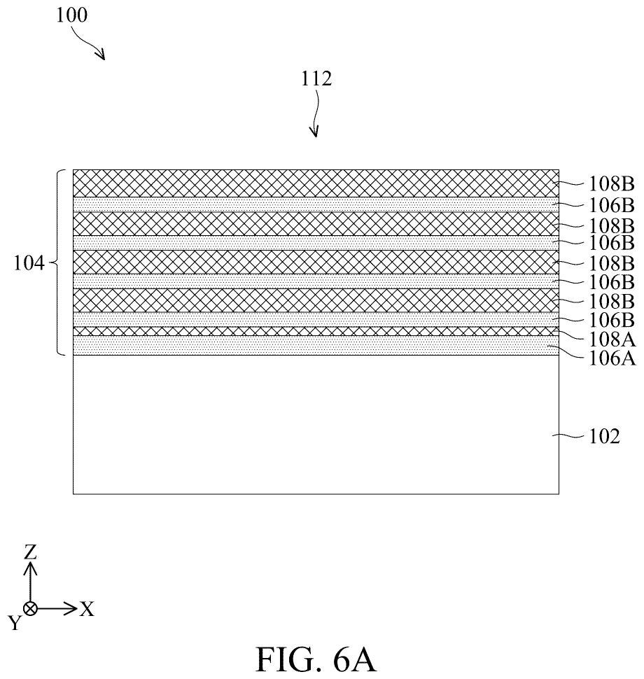

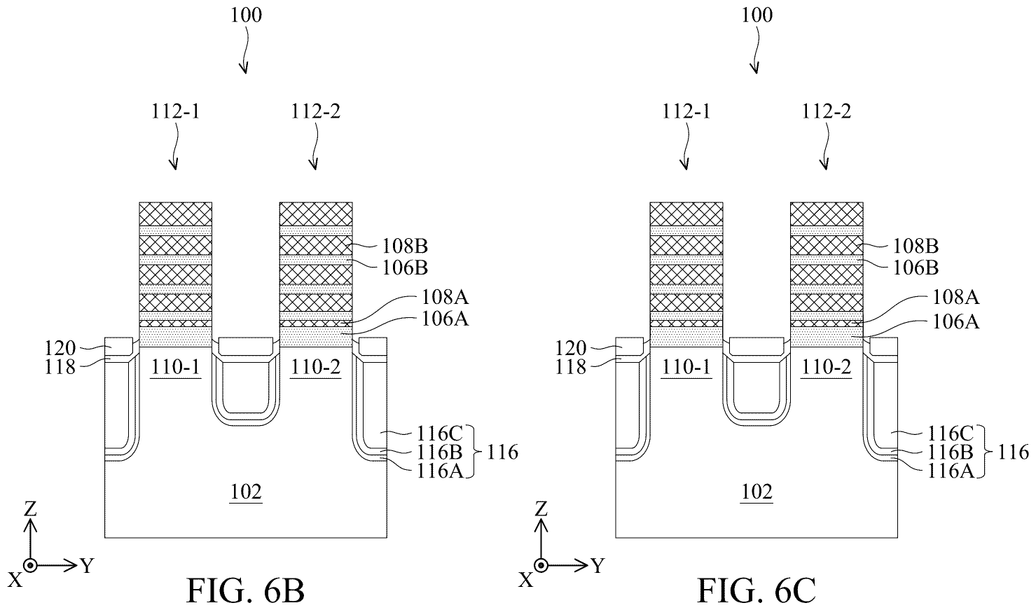

FIGS. 6B, 7B, 8B, 9B, 10B, 11B, 12B, 13B, 14B, 15B, 16C, 17C, 18C and 19C are Y-Z cross-sectional views of the workpiece at various fabrication stages along a line C-C′ of FIG. 5, in accordance with some embodiments of the present disclosure.

FIGS. 6C, 7C, 8C, 9C, 10C, 11C, 12C, 13C, 14C, 15C, 16D, 17D, 18D and 19D are Y-Z cross-sectional views of the workpiece at various fabrication stages along a line D-D′ of FIG. 5, in accordance with some embodiments of the present disclosure.

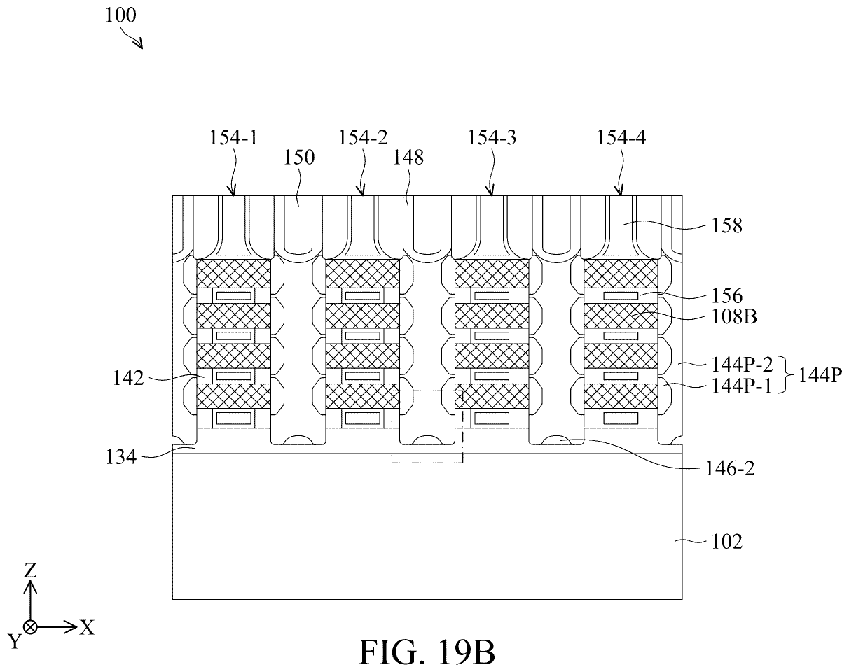

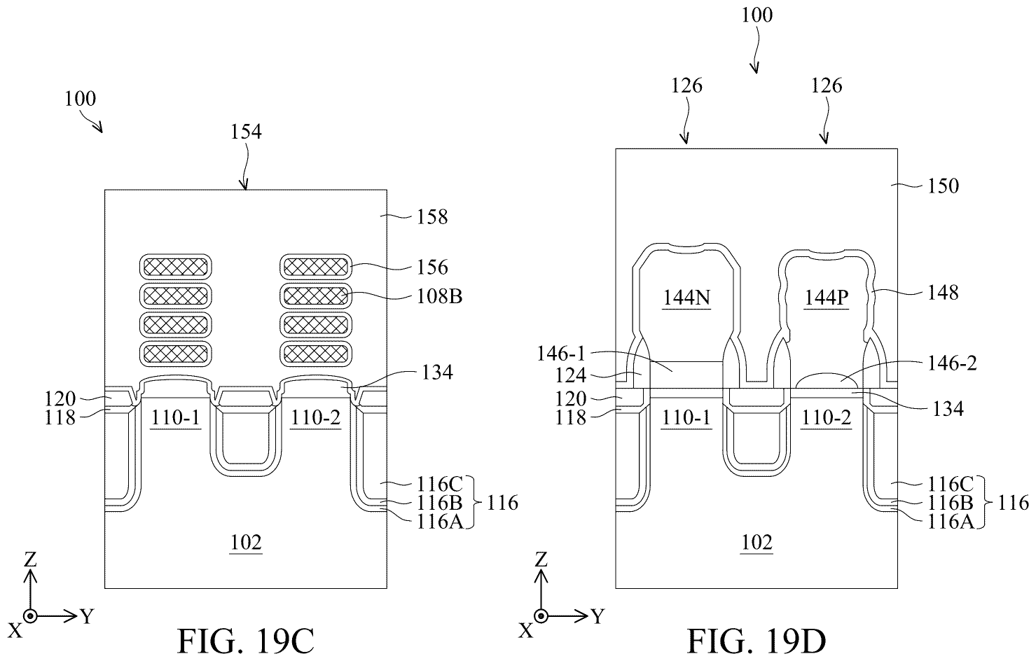

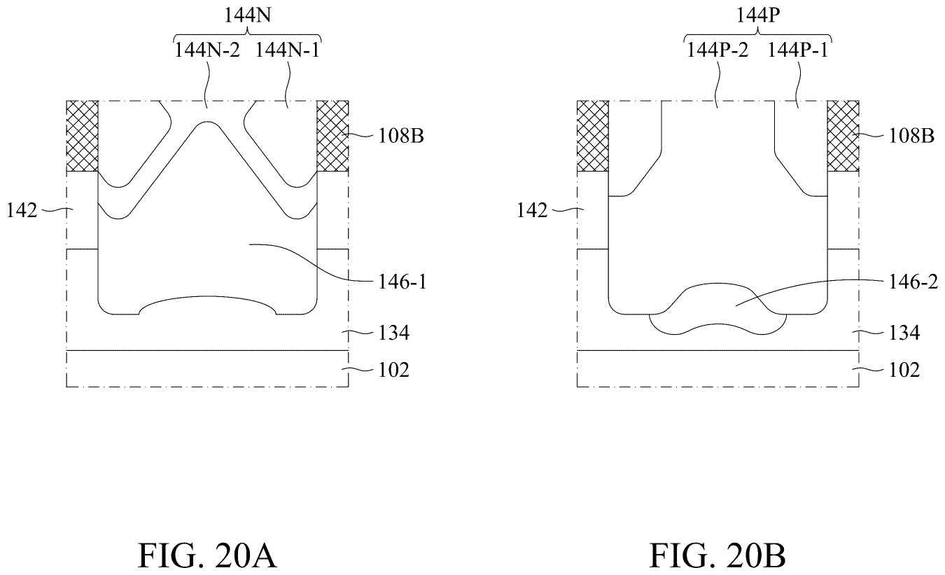

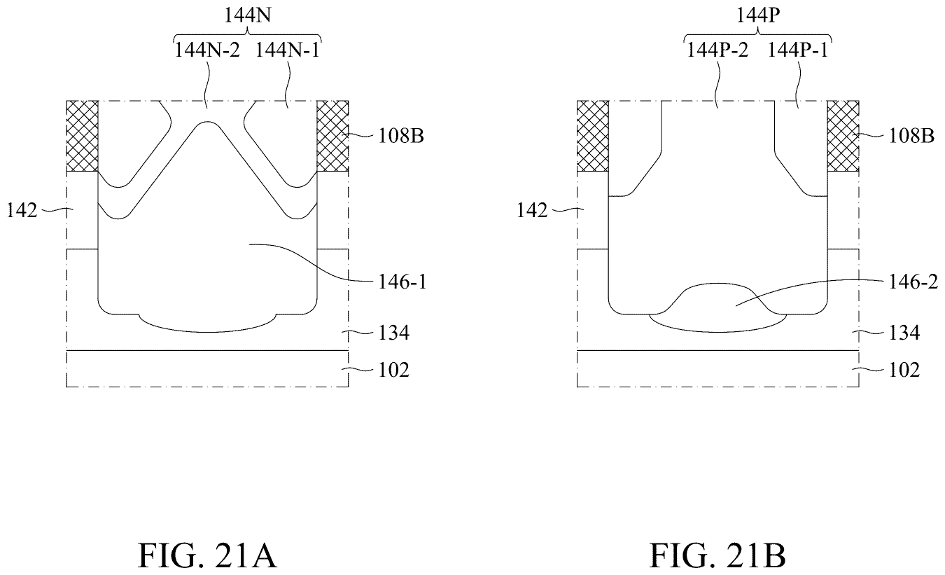

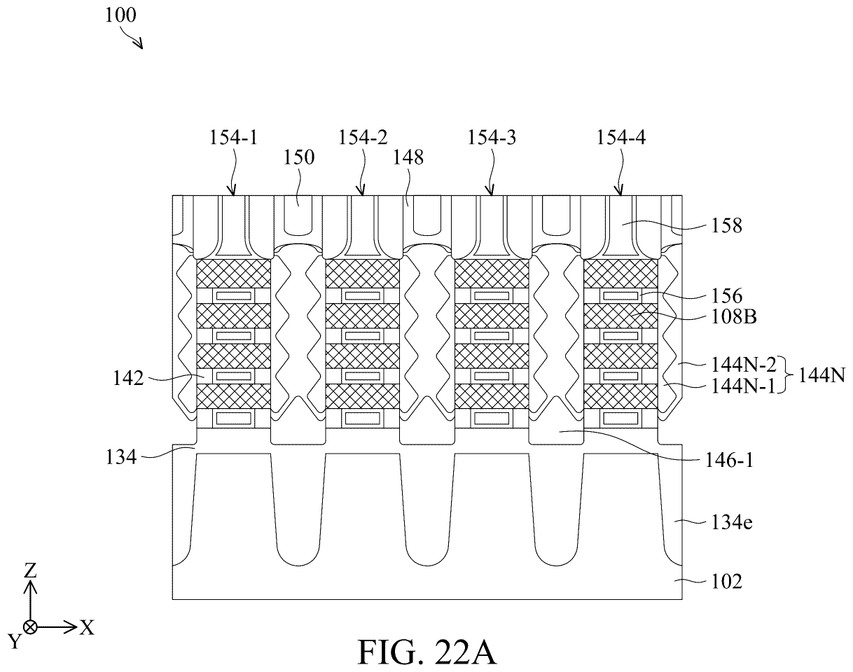

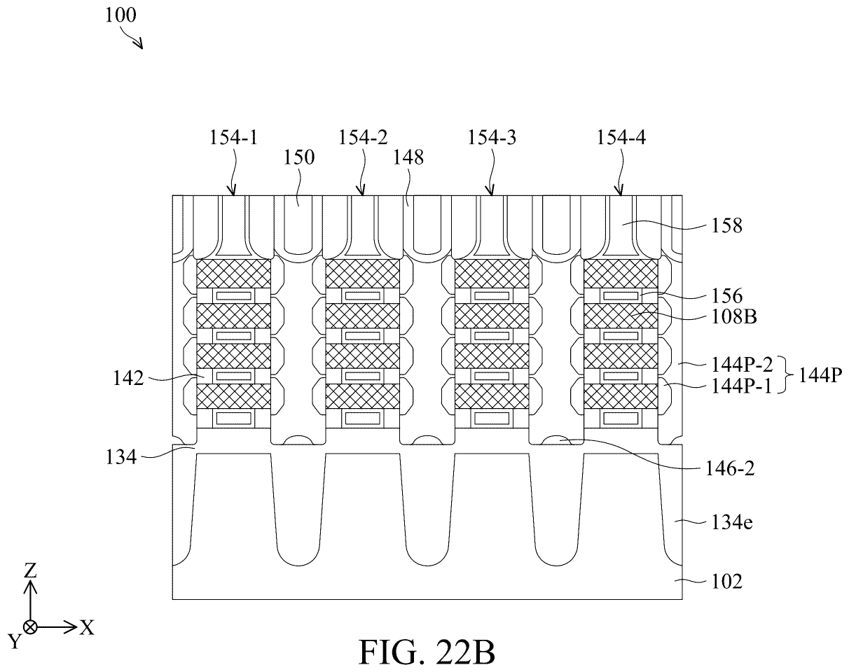

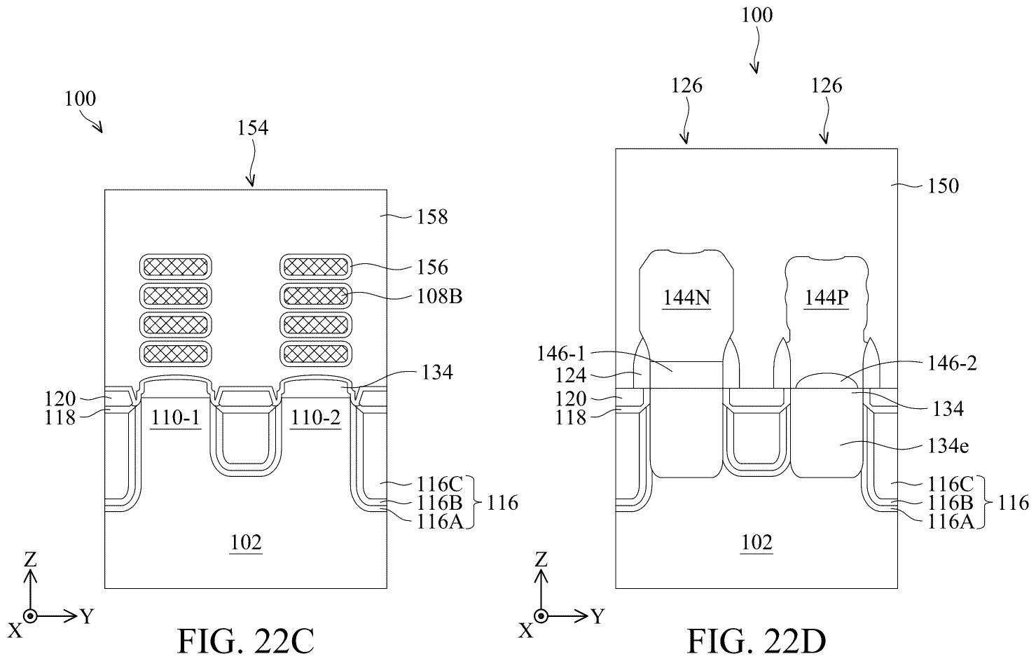

FIGS. 20A and 21A are partial enlarged cross-sectional views of the workpiece at the fabrication stage in a dashed box of FIG. 19A, in accordance with some alternative embodiments of the present disclosure.

FIGS. 20B and 21B are partial enlarged cross-sectional views of the workpiece at the fabrication stage in the dashed box of FIG. 19B, in accordance with some alternative embodiments of the present disclosure.

FIGS. 22A, 22B, 22C, and 22D are cross-sectional views of the workpiece at various fabrication stages along the line A-A′, B-B′, C-C′, and D-D′ of FIG. 5, respectively, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including dielectric layers under gate structures and source/drain features and air gaps under the source/drain features, such that the parasitic capacitance of the GAA transistor is reduced, thereby improving the performance of the GAA transistor. The details of the structure and manufacturing methods of the present disclosure are described below in conjunction with the accompanying drawings, which illustrate the process of making GAA transistor structures, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated. The X-direction, the Y-direction, and the Z-direction can be arbitrarily referred to as the first direction, the second direction, or the third direction in the order of appearance. For example, the Z-direction can be referred to as the first direction, and one of the X-direction and the Y-direction can be referred to as the second direction, and the other one of the X-direction and the Y-direction can be referred to as the third direction.

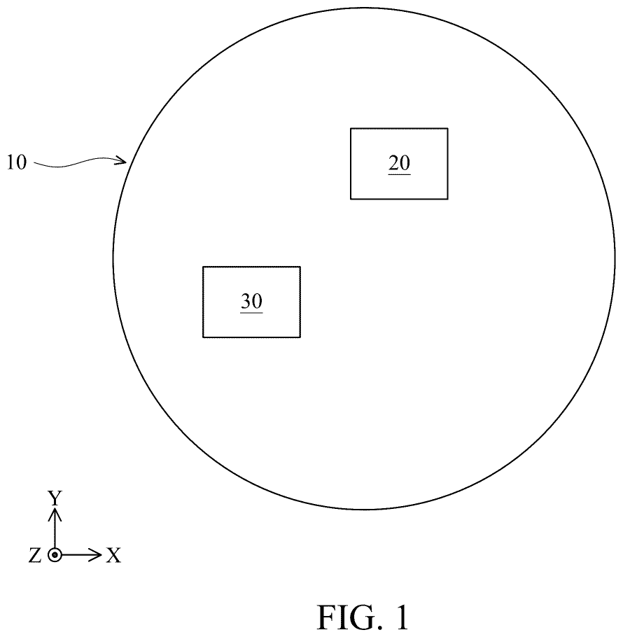

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or a combination thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable memory devices, or combinations thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or combinations thereof.

The logic region 30 can include an array of circuit cells having various logic cells or standard (STD) cells. The logic cells or STD cells may include transistors and interconnection structures that combine to provide a logic device and/or a logic function, such as an inverter, an AND, a NAND, an OR, a NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

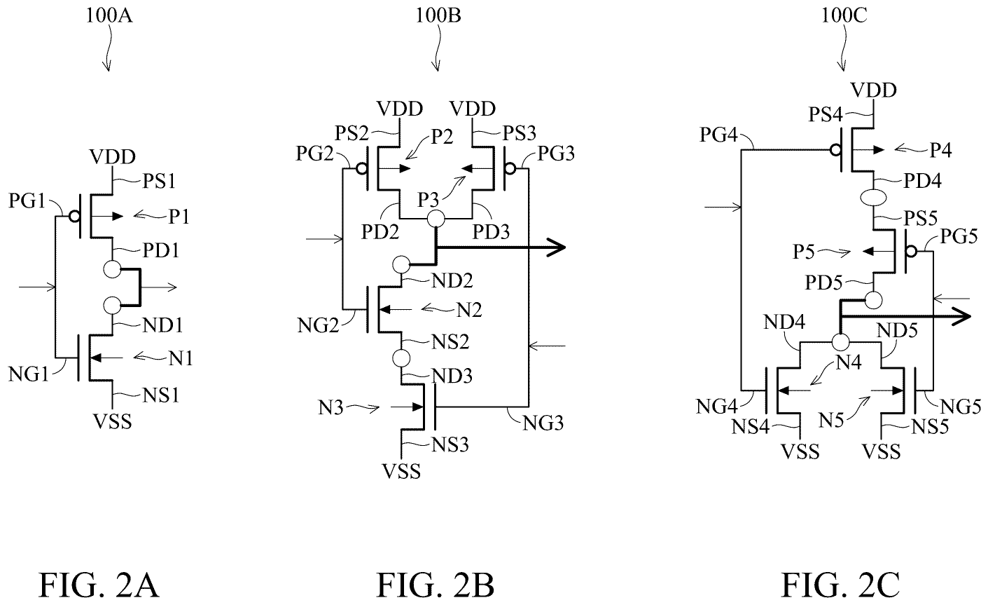

FIGS. 2A to 2E are circuit schematics of various STD cells in the array of circuit cells in the logic region 30 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

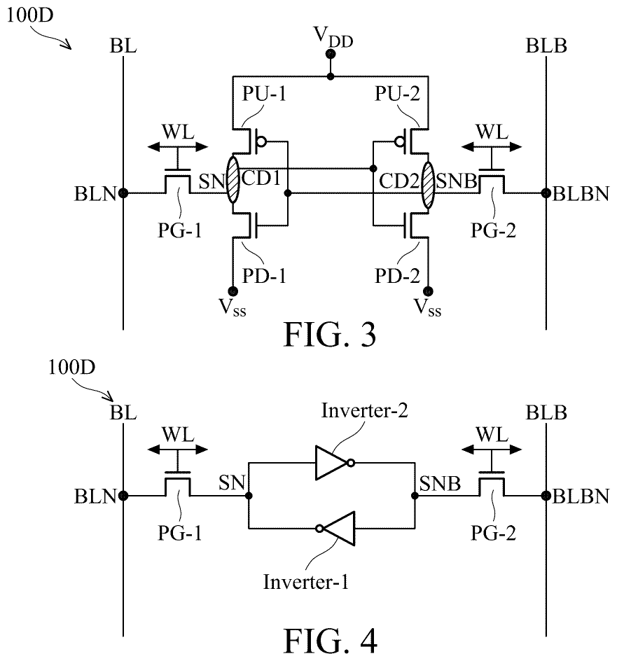

FIGS. 3 and 4 are circuit diagrams of an SRAM circuit that can be implemented in an SRAM cell of an array in the memory region 20 of FIG. 1, in accordance with some embodiments of the present disclosure. The circuit diagram of SRAM cell is merely exemplary, and in some embodiments, each of SRAM cells in the array is configured with an SRAM circuit similar to the SRAM cells 100D as shown in FIGS. 2 and 3. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inverter-2, and pass-gate transistor PG-2 is connected to an output of Inverter-2 and an input of Inverter-1.

In operation, pass-gate transistor PG-1 and pass-gate transistor PG-2 provide access to the storage portion of their respective SRAM cell (i.e., Inverter-1 and Inverter-2) and can also be referred to as access transistors of their respective SRAM cell. Each of SRAM cells is connected to and powered through a first power supply voltage, such as a positive power supply voltage, and a second power supply voltage, such as a ground voltage or a reference voltage (which can be an electrical ground).

A gate of pull-up transistor PU-1 interposes a source, which is electrically coupled to the first power supply voltage via a voltage node (or voltage source) V_{DD}, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) V_{SS}, and the first common drain.

A gate of pull-up transistor PU-2 interposes a source, which is electrically coupled to the first power supply voltage via voltage node V_{DD}, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node V_{SS}, and the second common drain.

The first common drain provides a storage node SN that stores data in true form, and the second common drain provides a storage node SNB that stores data in complementary form, or vice versa, in some embodiments. The gate of pull-up transistor PU and the gate of pull-down transistor PD-1 are coupled together and to the second common drain SD2, and the gate of pull-up transistor PU-2 and the gate of pull-down transistor PD-2 are coupled together and to the first common drain SD1.

A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2.

Gates of pass-gate transistors PG-1, PG-2 are connected to and controlled by a word line WL, which allows selection of a respective SRAM cell for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to the gates of the pass-gate transistors PG-1, PG-2 by the word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs.

FIGS. 3 and 4 have been simplified for the sake of clarity to better understand the inventive concepts of the present disclosure. Additional features can be added in the SRAM circuits of FIGS. 3 and 4, and some of the features described herein can be replaced, modified, or eliminated in other embodiments of the SRAM circuits of FIGS. 3 and 4.

Each of the circuit cells and the SRAM cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, exemplary GAA transistors for the circuit cells and the SRAM cells discussed above are illustrated and described below. More specifically, the manufacturing method and the structure of GAA transistors with improved dielectric layer between nanostructures and substrate for the circuit cells and the SRAM cells discussed above are illustrated and described below. However, it should be understood that the application should not be limited to a particular type of device, except as specifically claimed.

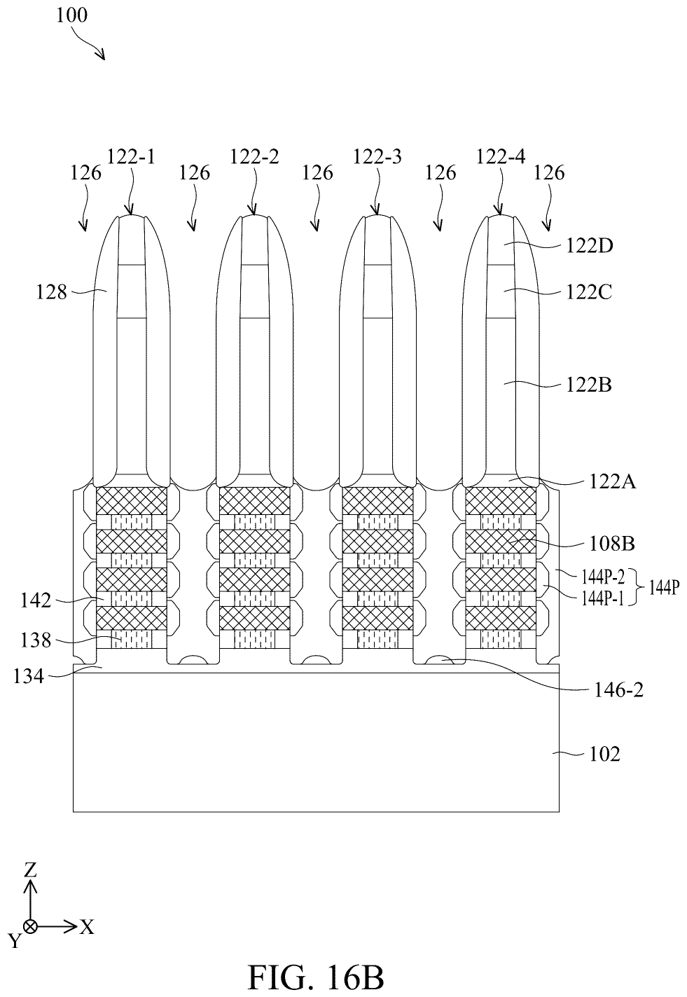

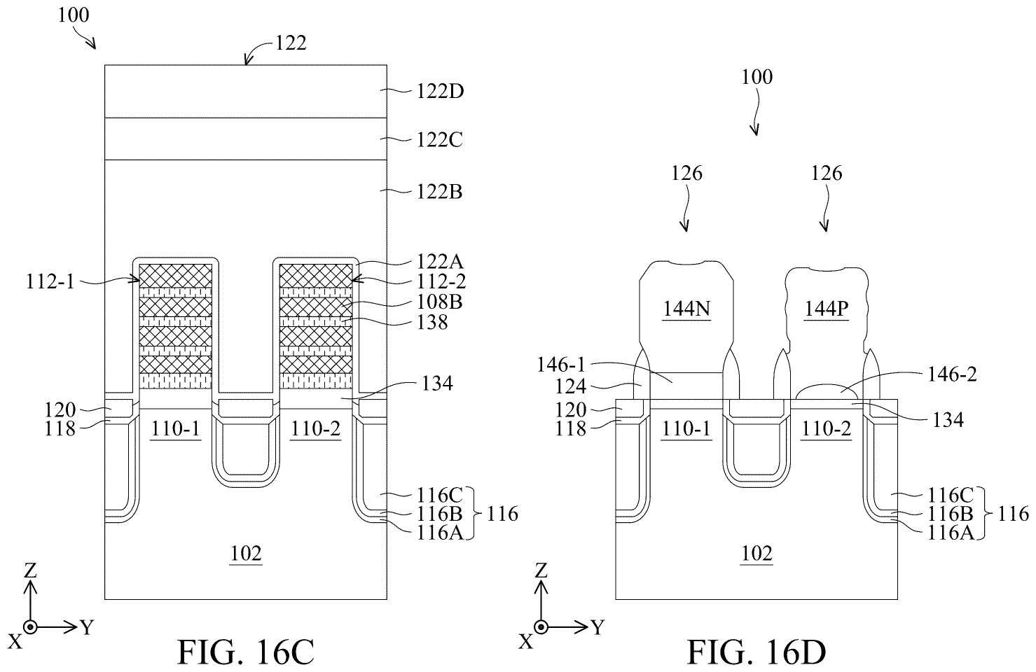

FIG. 5 is a perspective view of a workpiece 100 at a fabrication stage, in accordance with some embodiments of the present disclosure. FIGS. 6A, 7A, 8A, 9A, 10A, 11A, 12A, 13A, 14A, and 15A are X-Z cross-sectional views of the workpiece 100 at various fabrication stages along a line A-A′ or a line B-B′ of FIG. 5, in accordance with some embodiments of the present disclosure. FIGS. 16A, 17A, 18A, and 19A are X-Z cross-sectional views of the workpiece 100 at various fabrication stages along the line A-A′ of FIG. 5, in accordance with some embodiments of the present disclosure. FIGS. 16B, 17B, 18B, and 19B are X-Z cross-sectional views of the workpiece 100 at various fabrication stages along the line B-B′ of FIG. 5, in accordance with some embodiments of the present disclosure. FIGS. 6B, 7B, 8B, 9B, 10B, 11B, 12B, 13B, 14B, 15B, 16C, 17C, 18C and 19C are Y-Z cross-sectional views of the workpiece 100 at various fabrication stages along a line C-C′ of FIG. 5, in accordance with some embodiments of the present disclosure. FIGS. 6C, 7C, 8C, 9C, 10C, 11C, 12C, 13C, 14C, 15C, 16D, 17D, 18D and 19D are Y-Z cross-sectional views of the workpiece 100 at various fabrication stages along a line D-D′ of FIG. 5, in accordance with some embodiments of the present disclosure.

Referring to FIG. 5, the workpiece 100 is provided. The workpiece 100 may include a substrate 102 and a stack 104 over the substrate 102. In some embodiments, the substrate 102 contains a semiconductor material, such as bulk silicon (Si). Alternatively or additionally, in some other embodiments, another elementary semiconductor, such as germanium (Ge) in a crystalline structure, may also be included in the substrate 102. The substrate 102 may also include a compound semiconductor, such as silicon germanium (SiGe) or a III-V semiconductor material. Example III-V semiconductor materials may include silicon carbide (SiC), indium arsenide (InAs), indium antimonide (InSb), indium phosphide (InP), gallium arsenide (GaAs), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and/or indium gallium arsenide (InGaAs), or combinations thereof. The substrate 102 may also include an insulating layer, such as a silicon oxide layer, to have a semiconductor-on-insulator substrate, such as Si-on-insulator (SOI), SiGe-on-insulator (SGOI), Ge-on-insulator (GOI) substrates.

In some embodiments, the substrate 102 may include various doped regions configured according to design requirements of GAA transistors. In some embodiments, the substrate 102 may include a doped region 102W (also referred to as a well region). The doped region 102W may be an n-type doped region (also referred to as an n-well) or a p-type doped region (also referred to as a p-well), and the n-type doped region is configured for a p-type metal-oxide-semiconductor (PMOS) transistor and the p-type doped region is configured for an n-type MOS (NMOS) transistor. N-type doped region is doped with n-type dopants, such as phosphorus (P), arsenic (As), other n-type dopant, or combinations thereof. P-type doped region is doped with p-type dopants, such as boron (B), indium (In), other p-type dopant, or combinations thereof.

In the present embodiment, the substrate 102 shows one doped region 102W. In other embodiments, the substrate 102 may include multiple doped regions formed with a combination of p-type dopants and n-type dopants. An ion implantation process, a diffusion process, and/or other suitable doping process can be performed to form the various doped regions. In some embodiments, the n-type doped region has an n-type dopant concentration of about 5×10¹⁶ cm⁻³ to about 5×10¹⁹ cm⁻³, and the p-type doped region has a p-type dopant concentration of about 5×10¹⁶ cm⁻³ to about 5×10¹⁹ cm⁻³. Because the workpiece 100 will be fabricated into a semiconductor structure 100 upon conclusion of the fabrication processes, the workpiece 100 may be referred to as the semiconductor structure 100 as the context requires.

The stack 104 includes semiconductor layers 106 (including a semiconductor layers 106A and semiconductor layers 106B) and semiconductor layers 108 (including a semiconductor layers 108A and semiconductor layers 108B), and the semiconductor layers 106 and 108 are alternatingly stacked in the Z-direction. More specifically, the semiconductor layers 106B and 108B are alternatingly stacked in the Z-direction, the semiconductor layer 108A is under the semiconductor layers 106B and 108B, and the semiconductor layer 106A is under the semiconductor layers 106A, 106B, and 108B. In other words, the semiconductor layer 108A is over the semiconductor layer 106A and under the semiconductor layers 106B and 108B. In some aspects, the semiconductor layer 108A is between the (bottommost) semiconductor layer 106B and the semiconductor layer 106A. As shown in FIG. 5, a thickness of the semiconductor layer 108A is less than a thickness of the semiconductor layers 106 and a thickness of the semiconductor layers 108B.

The semiconductor layers 106 and the semiconductor layers 108 may have different semiconductor compositions. In some embodiments, semiconductor layers 106 are formed of silicon germanium (SiGe) and the semiconductor layers 108 are formed of silicon (Si). In these embodiments, the additional germanium content in the semiconductor layers 106 allow selective removal or recess of the semiconductor layers 106 without substantial damages to the semiconductor layers 108, so that the semiconductor layers 106 are also referred to as sacrificial layers. Furthermore, the semiconductor layers 106A and 106B have different germanium concentrations. More specifically, the germanium concentration of the semiconductor layer 106A is greater than the germanium concentration of the semiconductor layers 106B. In some embodiments, the germanium concentration of the semiconductor layer 106A is greater than about 60%.

In some embodiments, the semiconductor layers 106 and 108 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 106 and the semiconductor layers 108 are deposited alternatingly, one-after-another, to form the stack 104.

It should be noted that four (5) layers of the semiconductor layers 106 and five (5) layers of the semiconductor layers 108 are alternately and vertically arranged (or stacked) as shown in FIG. 5, which are for illustrative purposes only and not intended to be limiting beyond what is specifically recited in the claims. The number of layers depends on the desired number of channel members for the semiconductor device (more specifically, the number of the semiconductor layers 106B). In some embodiments, there may be from 2 to 10 semiconductor layers 106 alternating with 2 to 10 semiconductor layers 108 in the stack 104.

Referring to FIGS. 6A to 6C, the substrate 102 and the stack 104 are then patterned to form fins 112-1 and 112-2 (may be collectively referred to as fins 112) over the substrate 102. As shown in FIGS. 6A to 6C, each of the fins 112 includes a base fin 110 (i.e., the base fins 110-1 and 110-2 of the substrate 102) formed from the substrate 102 and a stack portion formed from the stack 104 over the base portion. In some aspects, the base fins 110-1 and 110-2 protrude from the substrate 102. Each of the fins 112 may include the semiconductor layers 106 and 108 alternating stacked in the Z-direction. The fins 112 extend lengthwise (e.g., longitudinally) in the X-direction, extend vertically in the Z-direction over the substrate 102, and are arranged in the Y-direction, as shown in FIGS. 6A to 6C. In some embodiments, widths of the fins 112 in the Y-direction are the same. Although two fins 112 are formed and shown herein, less or more fins may be formed, such as three or more fins.

The fins 112 may be patterned using suitable processes including double-patterning or multi-patterning processes. For example, in some embodiments, a material layer is formed over the substrate 102 and patterned into hard mask layers using a photolithography process. One or more etching processes are then performed to etch the stack 104 and top portions of the substrate 102 not covered by the hard mask layers to form the fins 112. The etching process may include dry etching, wet etching, reactive ion etching (RIE), and/or other suitable processes.

Still referring to FIGS. 6A to 6C, isolation features (or isolation structures) 116 are formed. More specifically, after the fins 112 are formed, the isolation features 116 are formed over the substrate 102. In some embodiments, the isolation features 116 extend in the X-direction (not shown) and are arranged with the fins 112 in the Y-direction (shown in FIGS. 6B and 6C). In some aspects, the isolation structures 116 are formed between the fins 112. In some other aspects, the isolation features 116 are formed around the fins 112. Furthermore, the isolation features 116 are also formed between the base fins 110-1 and 110-2 of the substrate 102, as shown in FIGS. 6B and 6C. More specifically, the isolation structures 116 are formed between and around the base fins 110-1 and 110-2 of the fins 112. In other aspects, the isolation features 116 are formed on opposite sides of the fins 112 (semiconductor layers 106 and 108) in the Y-direction.

The isolation features 116 may include different structures, such as shallow trench isolation (STI) structures and/or deep trench isolation (DTI) structures. In some embodiments, the isolation features 116 may also be referred to as shallow trench isolation (STI) feature. In some embodiments, the isolation features 116 may have a multi-layer structure such as one or more liner layer over the substrate 102 and a filling layer over the liner layer. More specifically, as shown in FIGS. 6B and 6C, each of the isolation features 116 are formed form a liner layer 116A, a liner layer 116B, and dielectric material 116C (i.e., the filling layer). Specifically, after the fins 112 are formed, a dielectric layer for the liner layers 116A is conformally formed on sidewalls of the fins 112 and over the fins 114 and the substrate 102. Then, a dielectric layer for the liner layer 101B is conformally formed on sidewalls of the dielectric layer for the liner layers 116A and over dielectric layer for the liner layers 116A. In order to form high quality liner layers 116A and 116B, the dielectric layers for the liner layers 116A and 116B are formed by performing atomic layer deposition (ALD) processes.

In some embodiments, the dielectric layer for the liner layers 116A includes silicon oxide (SiO₂) and the dielectric layer for the liner layers 116B includes silicon nitride (Si₃N₄). Therefore, the liner layers 204 may also be referred to as silicon oxide layers, oxide layers or liner oxide layers, and the liner layers 204 may also be referred to as silicon nitride layers, nitride layers or liner nitride layers.

After the formation of the dielectric layers for the liner layers 116A and 116B, a dielectric material 116C is deposited over the workpiece 100. In some embodiments, the dielectric material 116C may include silicon oxide (SiO₂). In various embodiments, the dielectric material 116C may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material 116C is then thinned and planarized, for example by a chemical mechanical polishing (CMP) process. The planarized dielectric material 116C, the liner layer 116A, and the liner layer 116B are further recessed by a dry etching process, a wet etching process, and/or a combination thereof to form the isolation features 116. Furthermore, as shown in FIGS. 6B and 6C, the stack portions of the fins 112 rise above the isolation features 116 while the base fins 110 are surrounded by the isolation features 116. In other words, top surfaces (or topmost surfaces) of the substrate 102 are higher than top surfaces of the isolation features 116.

Still referring to FIGS. 6A to 6C, after the formation of the isolation features 116, liner layers 118 and hard mask layers 120 are formed over the isolation features 116. More specifically, the liner layers 118 are conformally formed over and covers the isolation features 116, and between the fins 112, and then the hard mask layers 120 are formed over the isolation features 116 and the liner layers 118, and between the fins 112. In some aspects, the hard mask layers 120 are also formed in spaces in the liner layers 118, as shown in FIGS. 6B and 6C. In some embodiments, liner layers 118 include silicon oxide (SiO₂) and hard mask layers 120 include silicon nitride (Si₃N₄). Therefore, the liner layers 118 may also be referred to as silicon oxide layers, oxide layers or liner oxide layers, and then hard mask layers 120 may also be referred to as silicon nitride layers, nitride layers or hard mask nitride layers.

As shown in FIGS. 6B and 6C, the liner layers 118 are vertically between and in contact with the hard mask layers 120 and the isolation features 116. Furthermore, as shown in FIGS. 6B and 6C, the liner layers 118 are between and in contact with the hard mask layers 120 and the fins 112 (more specifically, the semiconductor layers 106A). In other words, the hard mask layers 120 is separated from the fins 112 by the liner layers 118. In some aspects, the liner layers 118 is also on sidewalls of the hard mask layers 120, as shown in FIGS. 6B and 6C. In some embodiments, the top surfaces of the liner layers 118 are lower than the top surfaces of the hard mask layers 120. Furthermore, the top surfaces of the hard mask layers 120 are higher than the top surfaces of the base fins 110.

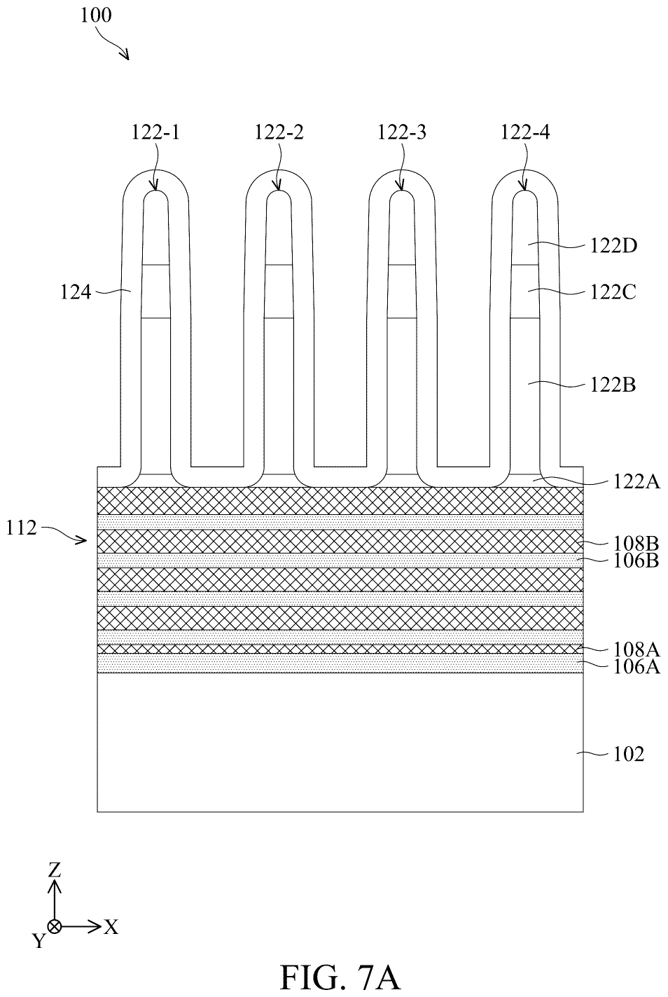

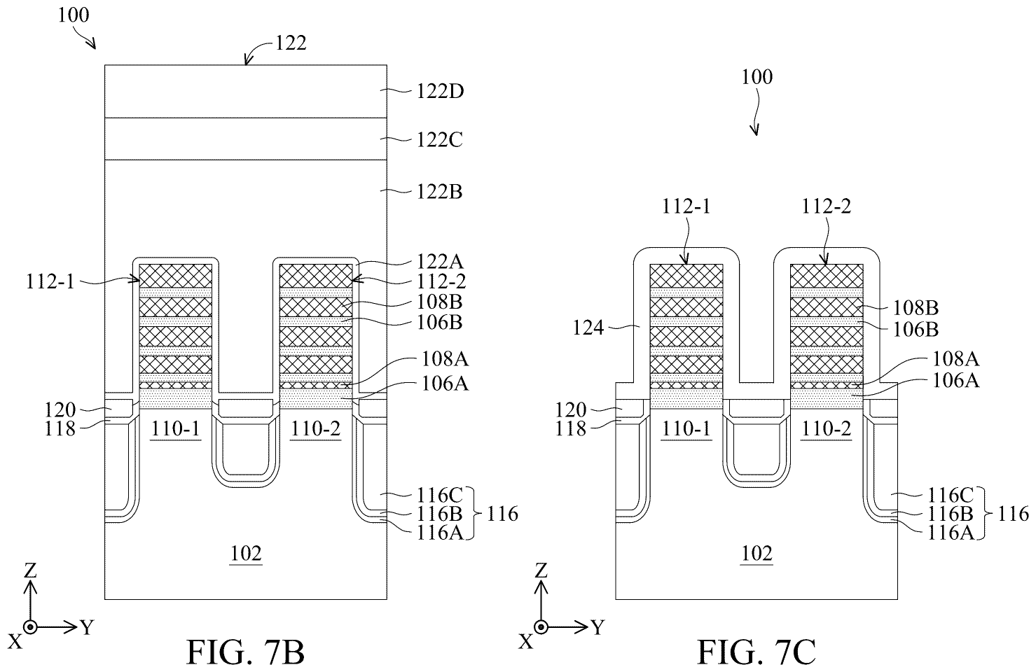

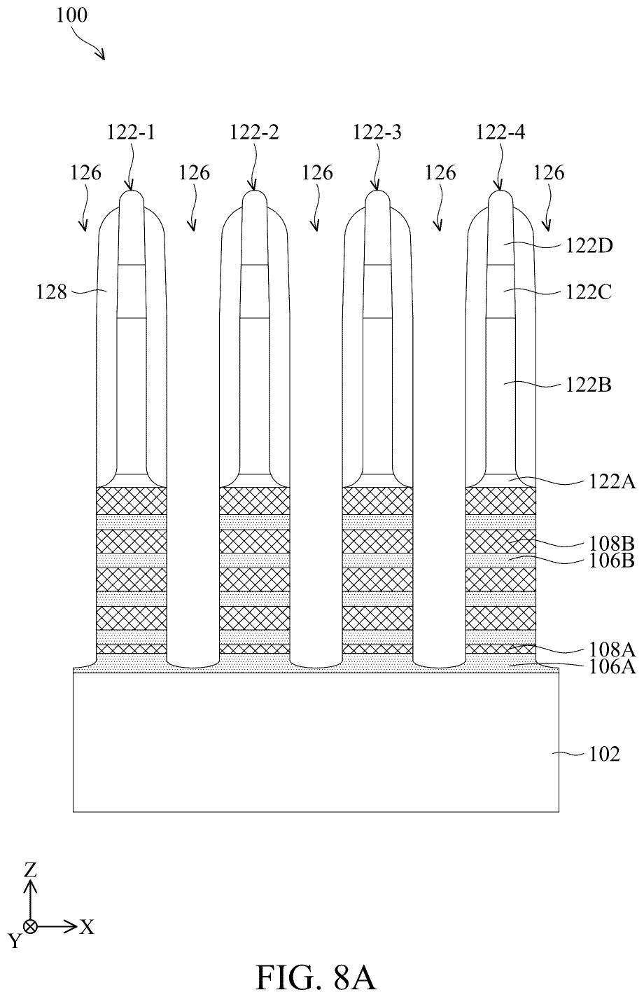

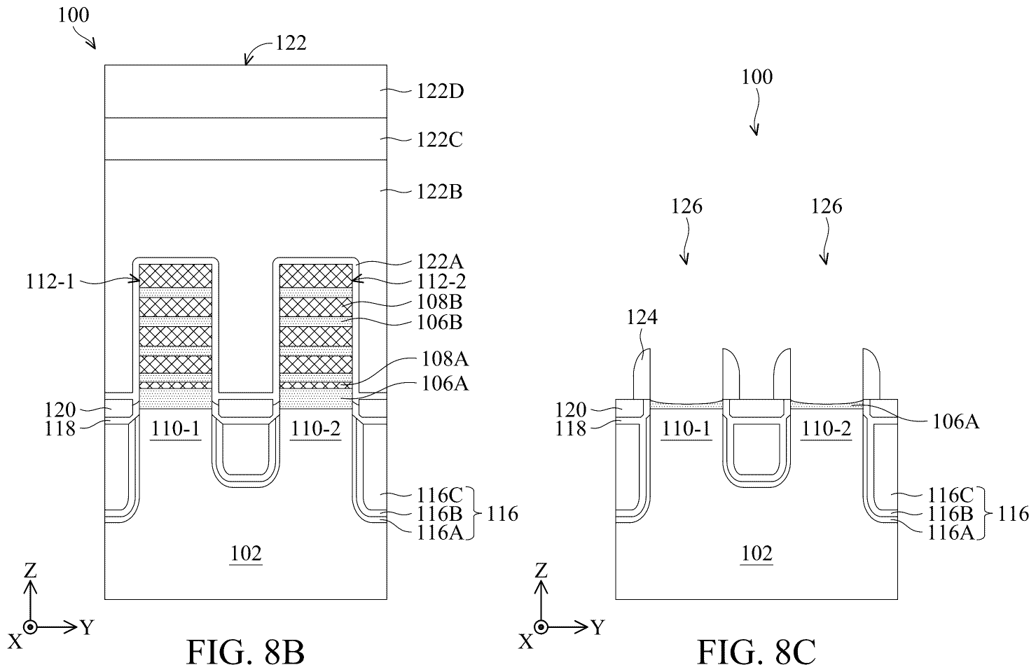

Referring to FIG. 8, dummy gate structures 122-1 to 122-4 (may be collectively referred to as dummy gate structures 122) may be formed over the fins 112, the isolation features 116, the hard mask layers 120, and the substrate 102. The dummy gate structures 122 may be configured to extend lengthwise in the Y-direction and wrap around top surfaces and side surfaces of the fins 112, as shown in FIG. 7B. In some embodiments, to form the dummy gate structures 122, a dummy interfacial material of a dummy interfacial layer 122A is first formed over the fins 112 and over the isolation features 116. More specifically, the dummy interfacial material is conformally formed on sidewalls of the fins 112 and over top surfaces of the fins 112 and the hard mask layers 120, as shown in FIG. 7B.

In some embodiments, the dummy interfacial layer 122A may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 122B is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., PVD, CVD, PECVD, and ALD).

Then, hard mask layers 122C and 122D are formed over the dummy gate material. In some embodiments, the hard mask layers 122C and 122D may be formed using photolithography and removal (e.g., etching) processes. In some embodiments, the hard mask layers 122C and 122D may include photoresist materials or hard mask materials. In some embodiments, the hard mask layer 122C may be a silicon nitride layer and the hard mask layer 122D may be a silicon oxide layer. After the formation of the hard mask layers 122C and 122D, lithography and etching processes may be performed to remove portions of the dummy gate material for the dummy gate electrode 122B and the dummy interfacial material for the dummy interfacial layer 122A that are not directly underlie the hard mask layers 122C and 122D, thereby forming the dummy gate structures 122 having the dummy interfacial layer 122A, the dummy gate electrode 122B, and the hard mask layers 122C and 122D. The dummy interfacial layer 122A may also be referred to as dummy gate dielectric. The dummy gate structure 122 may undergo a gate replacement process through subsequent processing to form metal gates, such as a high-k metal gate, as discussed in greater detail below.

FIG. 7A shows four dummy gate structures 122-1 to 122-4. In some embodiments, less or more dummy gate structures may be formed for one or more transistors sharing source/drain regions. In other embodiments, some dummy gate structures may also undergo a gate replacement process to form dielectric based gates that electrically isolate transistors formed by the dummy gate structure 122 from neighboring transistors or devices. For examples, dummy gate structures 122-1 and 122-3 may be replaced with dielectric material in sequent processes to form dielectric based gates to isolate resultant transistor formed from the dummy gate structures 122-2 and 122-3 from neighboring transistors or devices.

Still referring to FIGS. 7A to 7C, after the formation of the dummy gate structures 122, a spacer layer 124 is formed on top surfaces and sidewalls of the dummy gate structures 122, over top surfaces of the fins 112, and on sidewalls of the fins 112. More specifically, in some embodiments, the spacer layer 124 may be formed by conformally depositing the spacer layer 124 (containing the dielectric material) over the hard mask layers 120, the fins 112, and dummy gate structures 122. Additionally or alternatively, the formation of the spacer layer 124 may also involve chemical oxidation, thermal oxidation, ALD, CVD, and/or other suitable methods. The spacer layer 124 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The spacer layer 124 may include a single layer or a multi-layer structure.

Referring to FIGS. 8A to 8C, the fins 112 are recessed to form source/drain trenches 126 in the fins 112 (or passing through the semiconductor layers 106 and 108) exposed by the dummy gate structures 122. The source/drain trenches 126 are also formed on opposite sides of the dummy gate structures 122 in the X-direction, as shown in FIG. 8. More specifically, the source/drain trenches 126 may be formed by performing one or more etching processes to remove portions of the spacer layer 124, the semiconductor layers 106, and the semiconductor layers 108 that do not vertically overlap or be covered by the dummy gate structures 122. In some embodiments, a single etchant may be used to remove the portions of the spacer layer 124, the semiconductor layers 106, and the semiconductor layers 108, whereas in other embodiments, multiple etchants may be used to perform the etching process. As shown in FIG. 8A, the semiconductor layers 106 exposed in the source/drain trenches 126 are partially etched so that semiconductor layers 106 have concave surfaces.

Furthermore, as discussed above, the portions of the spacer layer 124 are removed, so that remain portions of spacer layer 124 become gate spacers 122 on opposite sides of the dummy gate structures 122 in the X-direction, as shown in FIG. 8A. As shown in FIG. 8C, portions of the spacer layer 124 on the sidewall surfaces of the fins 112 in the Y-direction (shown in FIG. 7C) remain in the source/drain trenches 126 and over the hard mask layers 120. The gate spacers 122 may also be interchangeably referred to as the top spacers.

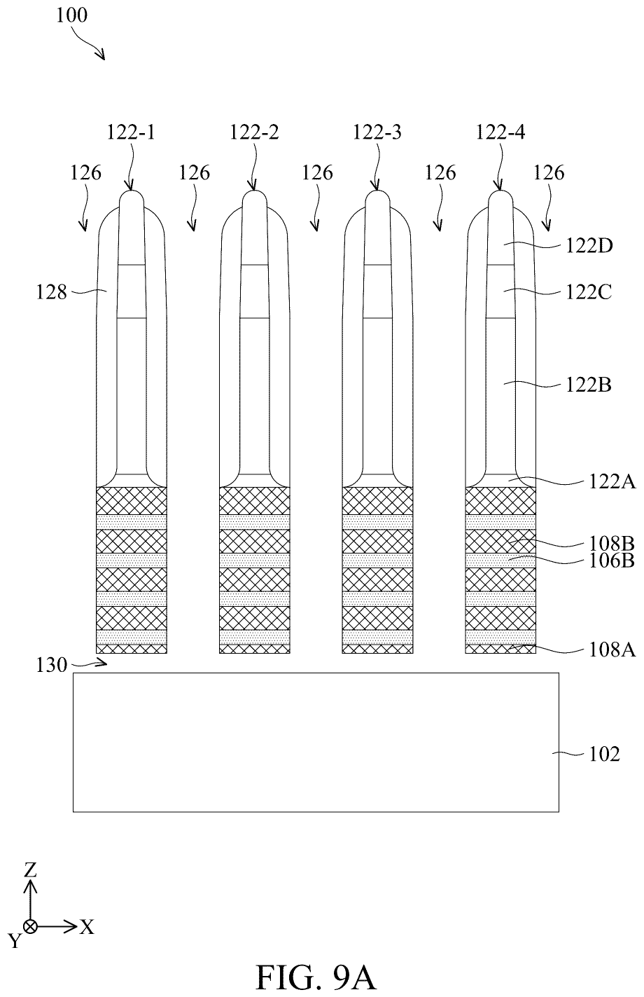

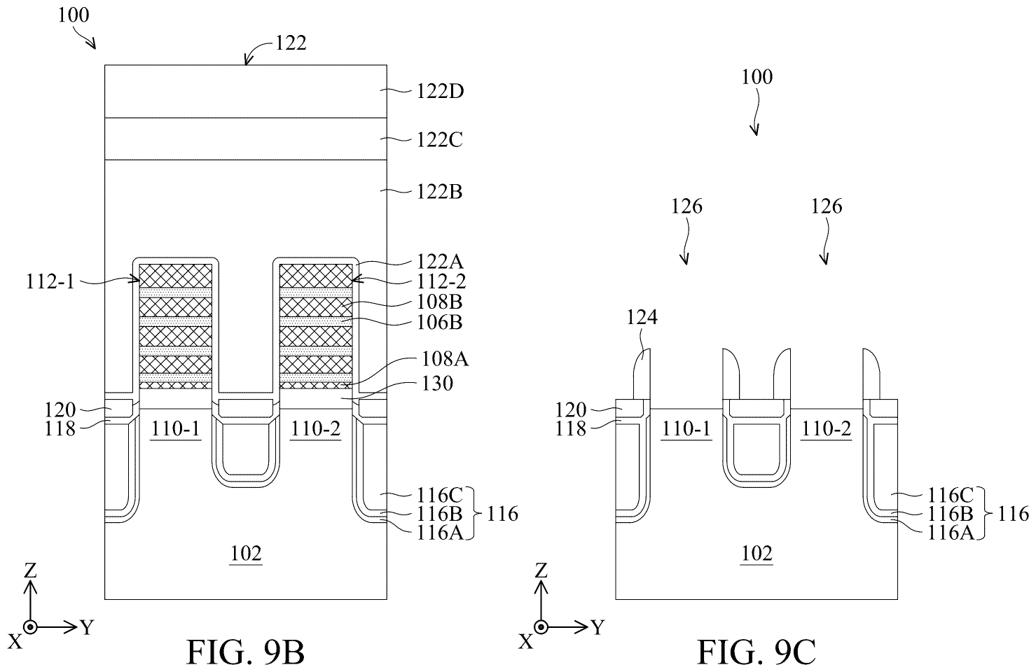

Referring to FIGS. 9A to 9C, the semiconductor layers 106A are removed through the source/drain trenches 126. The semiconductor layers 106A are removed by a selective etching process. More specifically, the selective etching process is performed that selectively etches the semiconductor layers 106A through the source/drain trenches 126, with minimal (or no) etching of the semiconductor layers 106B, the semiconductor layers 108, the gate spacers 128, the hard mask layers 120, and the substrate 102, such that gaps 130 are formed between the fins 112 (more specifically, the semiconductors 108A) and the substrate 102 in the Z-direction, below the gate spacers 128 and the dummy gate structures 122. The etching process is configured to laterally etch (e.g., along the X-direction) the semiconductor layer 106A below the gate spacers 128 and the dummy gate structures 122. The selective etching process is a dry etching process, a wet etching process, other suitable etching process, or combinations thereof.

It is noted that the semiconductor layers 106A is selectively removed without removing the semiconductor layers 106B due to the different germanium concentrations of the semiconductor layers 106A and 106B, as discussed above. Furthermore, the semiconductor layers 108A are disposed over the semiconductor layers 106A and under the semiconductor layers 106B and 108B. In other words, the semiconductor layers 108A cover and protect the bottom surfaces of the (bottommost) semiconductor layers 106B, such that the (bottommost) semiconductor layers 106B are separated from the semiconductor layers 106A. As such, the diffusion of the germanium from the semiconductor layers 106A (having high germanium concentration) to the (bottommost) semiconductor layers 106B (having low germanium concentration) is prevented, the selectivity between the semiconductor layers 106A and the (bottommost) semiconductor layers 106B remain. Therefore, the semiconductor layers 106A can be selectively removed without removing the (bottommost) semiconductor layers 106B.

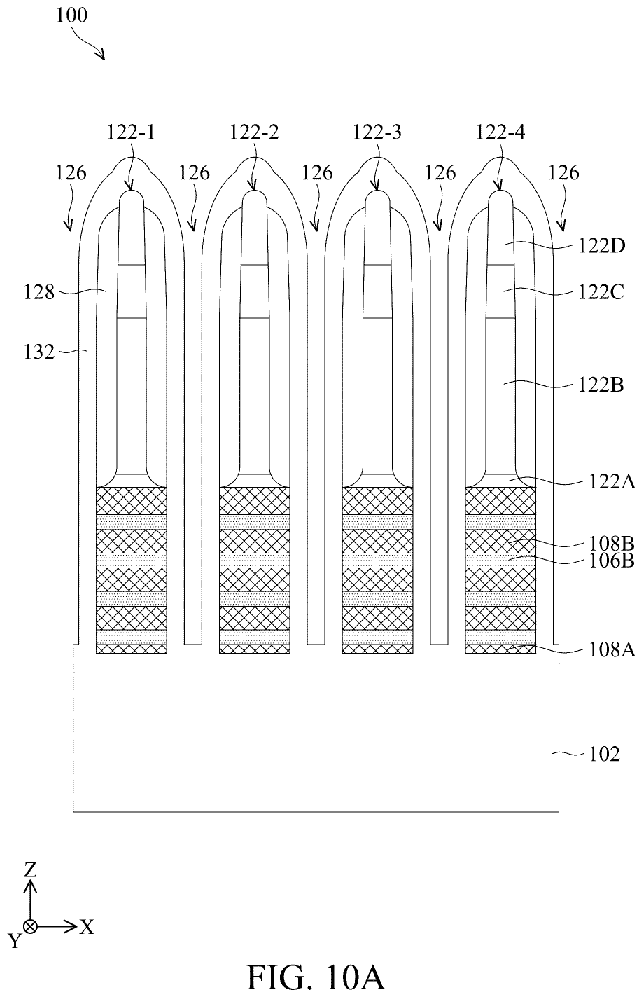

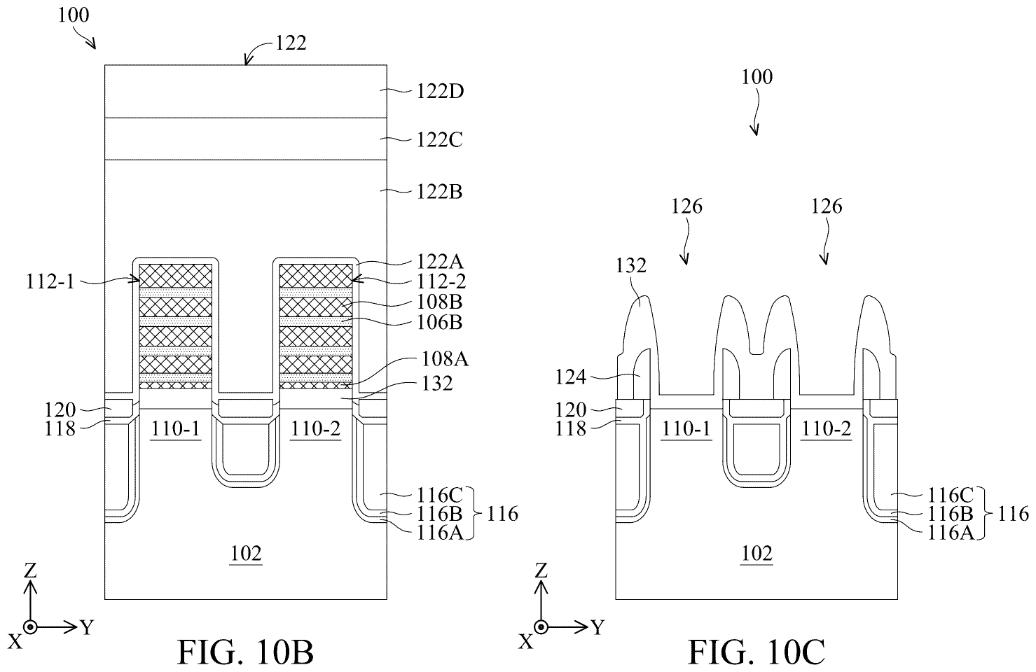

Referring to FIGS. 10A to 10C, a dielectric material 132 is conformally formed into the source/drain trenches 126 and the gaps 130. In some embodiments, a deposition process is performed to form the dielectric material 132 into the source/drain trenches 126 and the gaps 130, such as CVD, PVD, ALD, HDPCVD, MOCVD, RPCVD, PECVD, LPCVD, ALCVD, APCVD, other suitable methods, or combinations thereof. The dielectric material 132 partially fills the source/drain trenches 126 and fully fills the gaps 130, as shown in FIGS. 10A to 10C. More specifically, as shown in FIG. 10A, the dielectric material 132 is conformally formed on the top surfaces of the substrate 102 (exposed in the source/drain trenches 126 and the gaps 130), on sidewalls of the gate spacers 128, the semiconductor layers 106B, the semiconductor layers 108A and 108B, and over top surfaces of the gate spacers 128 and the dummy gate structures 122. As shown in FIG. 10C, the dielectric material 132 is also conformally formed on the top surfaces of the hard mask layers 120 and the spacer layer, and over the top surfaces of the spacer layer. Furthermore, the dielectric material 132 is also conformally formed on bottom surfaces of the semiconductor layers 108A exposed in the gaps 130, as shown in FIGS. 10A and 10B. The deposition process is configured to ensure that the dielectric material 132 fully fills the gaps 130 between the semiconductor layers 108A and the substrate 102 direct under the gate spacers 128 and the dummy gate structures 122.

The dielectric material 132 includes a material that is different than materials of the semiconductor layers 106 and 108, and a material of the gate spacers 128 (i.e., the spacer layer 124), to achieve the desired etching selectivity during the etching process. In some embodiments, the dielectric material 132 includes a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)).

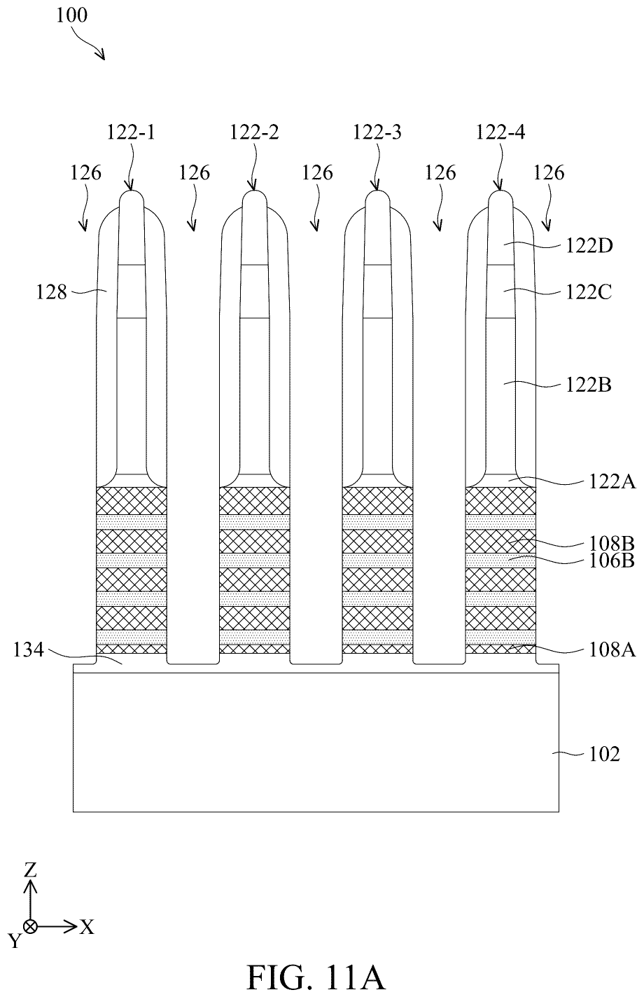

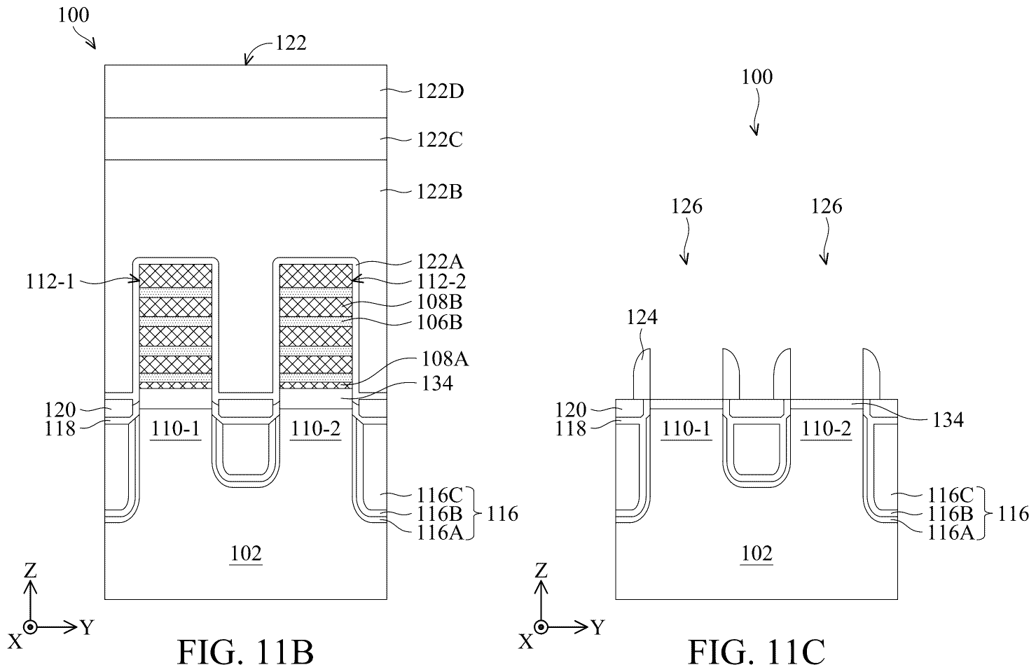

Referring to FIGS. 11A to 11C, one or more etching processes are performed to trim the dielectric material 132 to partially remove the dielectric material 132 to form dielectric layers 134 under the dummy gate structures 122, the semiconductor layers 106B and 108, and the gate spacers 128. More specifically, one or more etching processes are performed to partially remove the dielectric material 132 exposed in the source/drain trenches 126 and portions of the dielectric material 132 in the gaps 130 and on the top surfaces of the substrate 102 remain to form the dielectric layers 134. Therefore, the dielectric layers 134 are made of the dielectric material 132 and include Si₃N₄, SiO₂, SiC, SiOC, SiON, SiCN, SiOCN, or a combination thereof.

The one or more etching processes are selective etching processes that are performed to selectively etch portions of the dielectric material 132 exposed in the source/drain trenches 126 through the source/drain trenches 126, with minimal (or no) etching of the dummy gate structures 122, the semiconductor layers 106 and 108, the gate spacers 128, the hard mask layers 120, and the spacer layer 124 (shown in FIG. 11C). Furthermore, the dielectric material 132 on the top surfaces of the substrate 102 exposed in the source/drain trenches 126 are partially removed, such that the substrate 102 in the source/drain trenches 126 is still covered with the dielectric material 132 (i.e., the dielectric layers 134), as shown in FIGS. 11A to 11C.

The etching process may be an anisotropic etching process, such that the etching process is configured to vertically etch (e.g., along the Z-direction) the dielectric material 132 that do not vertically overlap or be covered by the dummy gate structure 122 and the gate spacers 128. Furthermore, the etching process is controlled to have a higher etching rate on the dielectric material 132 on the sidewalls of the gate spacers 128, the semiconductor layers 106B, the semiconductor layers 108A and 108B, such that the dielectric material 132 on the sidewalls of the gate spacers 128, the semiconductor layers 106B, the semiconductor layers 108A and 108B are removed and the dielectric material 132 on the top surfaces of the substrate 102 exposed in the source/drain trenches 126 are partially removed, as discussed above.

The selective etching process is a dry etching process, a wet etching process, other suitable etching process, or combinations thereof. As such, the dielectric material 132 is trimmed into the dielectric layers 134 between the semiconductor layers 108B and the substrate 102 direct under the dummy gate structures 122 and the gate spacers 128 and on the top surfaces of the substrate 102 exposed in the source/drain trenches 126, as shown in FIGS. 11A to 11C. Therefore, the semiconductor layers 106A discussed above are replaced with the dielectric layers 134.

As discussed above, the dielectric material 132 on the top surfaces of the substrate 102 exposed in the source/drain trenches 126 are partially removed. Therefore, in some embodiments, a thickness of the dielectric layers 134 on the top surfaces of the substrate 102 exposed in the source/drain trenches 126 is less than a thickness of the dielectric layers 134 between the semiconductor layers 108B and the substrate 102 direct under the dummy gate structures 122 and the gate spacers 128, as shown FIGS. 11A to 11C.

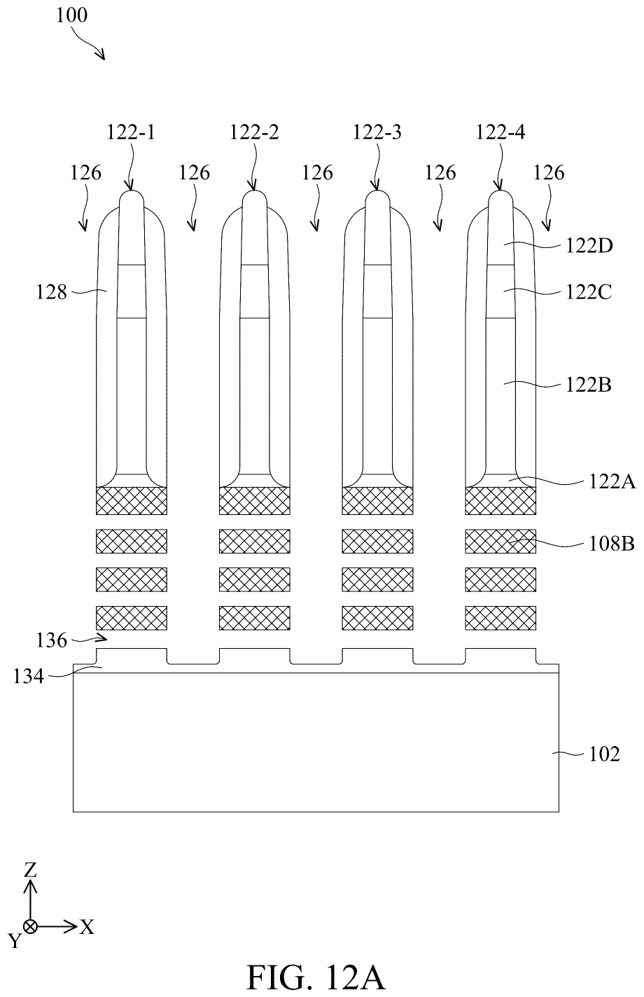

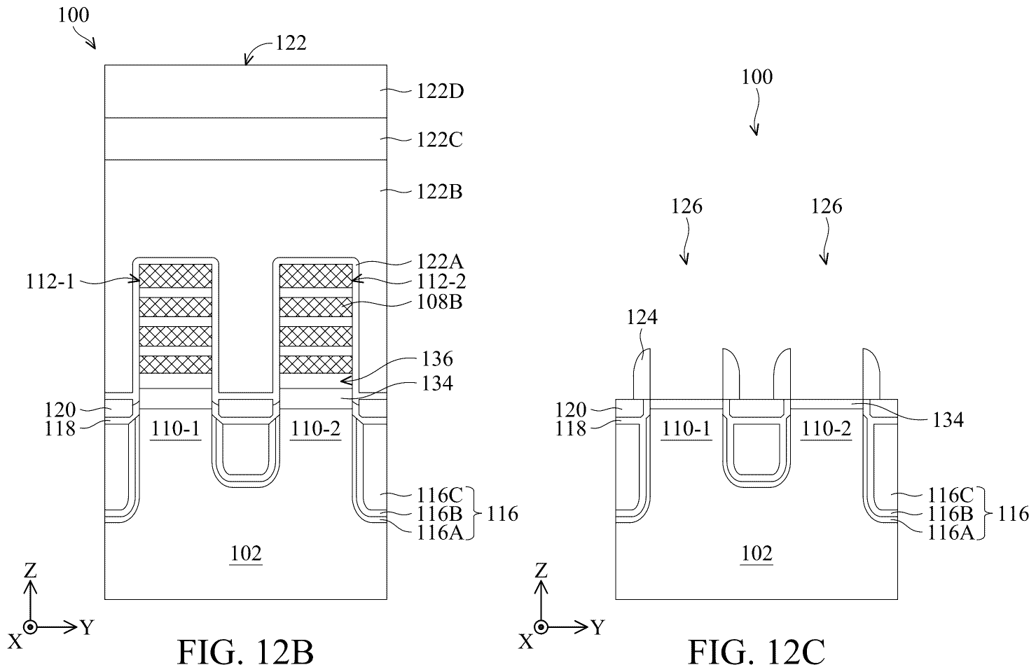

Referring to FIGS. 12A to 12C, the semiconductor layers 106B are removed via a selective etching process. More specifically, the selective etching process is performed that selectively etches the semiconductor layers 106B below the gate spacers 128 and the dummy gate structures 122 through the source/drain trenches 126, with minimal (or no) etching of semiconductor layers 108B, the gate spacers 128, the dielectric layers 134, the hard mask layers 120, and the spacer layer 124, such that gaps 136 are formed between the semiconductor layers 108B in the Z-direction as well as between the (bottommost) semiconductor layers 108B and the dielectric layers 134 in the Z-direction, below the gate spacers 128 and the dummy gate structures 122.

Furthermore, although the selective etching process is performed to selectively remove the semiconductor layers 106B, the semiconductor layers 108A are also removed due to the thin thickness of the semiconductor layers 108A (the thickness of the semiconductor layers 108A are less than the thickness of the semiconductor layers 106 and the thickness of the semiconductor layers 108B, as discussed above).

Therefore, top surfaces and bottom surfaces of the semiconductor layers 108B are exposed, below the gate spacers 128 and the dummy gate structures 122. The etching process is configured to laterally etch (e.g., along the X-direction) the semiconductor layers 106B below the gate spacers 128 and the dummy gate structures 122. The selective etching process is a dry etching process, a wet etching process, other suitable etching process, or combinations thereof.

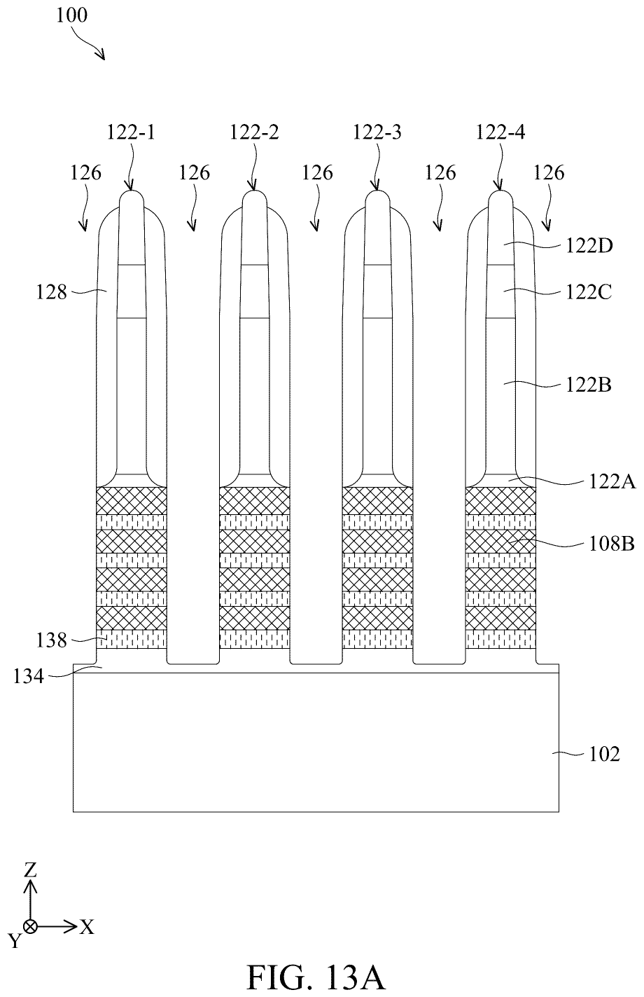

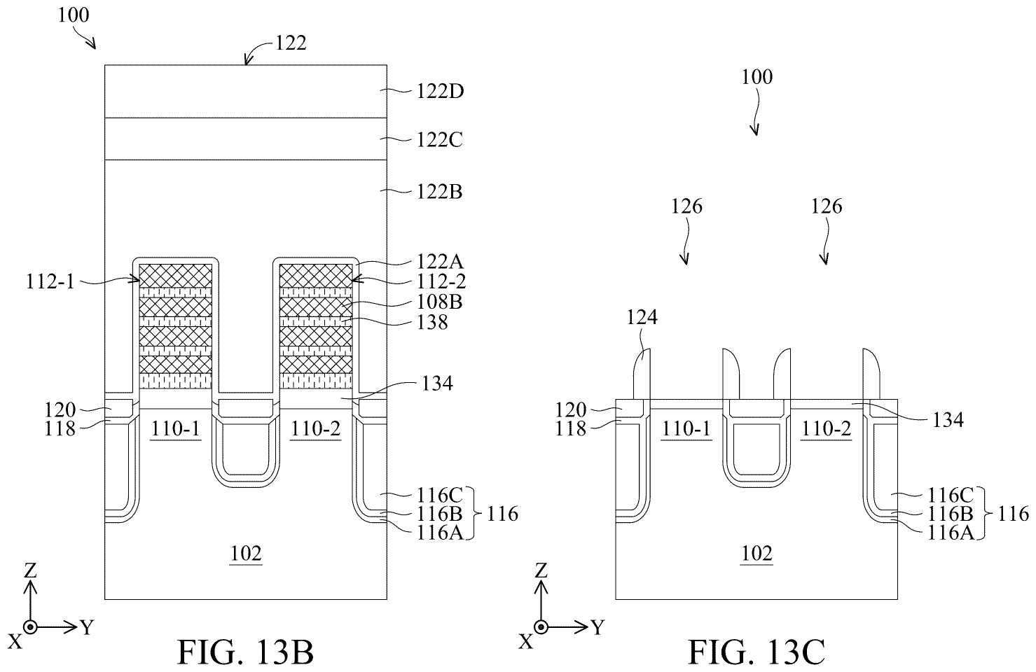

Referring to FIGS. 13A to 13C, dielectric layers 138 are formed to fill the gaps 136. More specifically, the dielectric layers 138 are formed between the semiconductor layers 108B in the Z-direction as well as between the (bottommost) semiconductor layers 108B and the dielectric layers 134 in the Z-direction, as shown in FIGS. 13A and 13B. In some embodiments, to form the dielectric layers 138, a dielectric material for the dielectric layers 138 is first conformally formed into the source/drain trenches 126 and the gaps 136. In some embodiments, a deposition process is performed to form the dielectric material for the dielectric layers 138 into the source/drain trenches 126 and the gaps 136, such as CVD, PVD, ALD, HDPCVD, MOCVD, RPCVD, PECVD, LPCVD, ALCVD, APCVD, other suitable methods, or combinations thereof.

The dielectric material for the dielectric layers 138 partially fills the source/drain trenches 126 and fully fills the gaps 136. More specifically, the dielectric material for the dielectric layers 138 is conformally formed on top surfaces of the dummy gate structures 122 and the dielectric layers 134 (exposed in the source/drain trenches 126 and the gaps 136), on sidewalls of the gate spacers 128, and the semiconductor layers 108B. Furthermore, the dielectric material for the dielectric layers 138 is also conformally formed on top surfaces and bottom surfaces of the semiconductor layers 108B exposed in the gaps 136. The deposition process is configured to ensure that the dielectric material for the dielectric layers 138 fully fills the gaps 136 between the semiconductor layers 108B as well as between the (bottommost) semiconductor layers 108B and the dielectric layers 134 direct under the gate spacers 128 and the dummy gate structures 122.

The dielectric material 132 of the dielectric layers 138 includes a material that is different than a material of the semiconductor layers 108B and a material of the gate spacers 128 to achieve desired etching selectivity during the etching process. In some embodiments, the dielectric material for the dielectric layers 138 includes silicon oxide (SiO₂).

After the formation of the dielectric material for the dielectric layers 138, one or more etching processes are performed to partially remove the dielectric material to form the dielectric layers 138. More specifically, one or more etching processes are performed to remove the dielectric material for the dielectric layers 138 exposed in the source/drain trenches 126. Therefore, the dielectric layers 138 are also made of the dielectric material including silicon oxide (SiO₂). In some embodiments, the dielectric layers 138 may also be referred to as silicon oxide layers or oxide layers.

The one or more etching processes are selective etching processes that are performed to selectively etch the dielectric material for the dielectric layers 138 exposed in the source/drain trenches 126, with minimal (or no) etching of the dummy gate structures 122, the semiconductor layers 108B, the gate spacers 128, the hard mask layers 120, and the dielectric layers 134. The selective etching process is a dry etching process, a wet etching process, other suitable etching process, or combinations thereof. As such, the dielectric layers 138 are formed between the semiconductor layers 108B in the Z-direction as well as between the (bottommost) semiconductor layers 108B and the dielectric layers 134 in the Z-direction direct under the gate spacers 128 and the dummy gate structures 122, as shown in FIGS. 13A and 13B. Therefore, the semiconductor layers 106B and 108A discussed above are replaced with the dielectric layers 138.

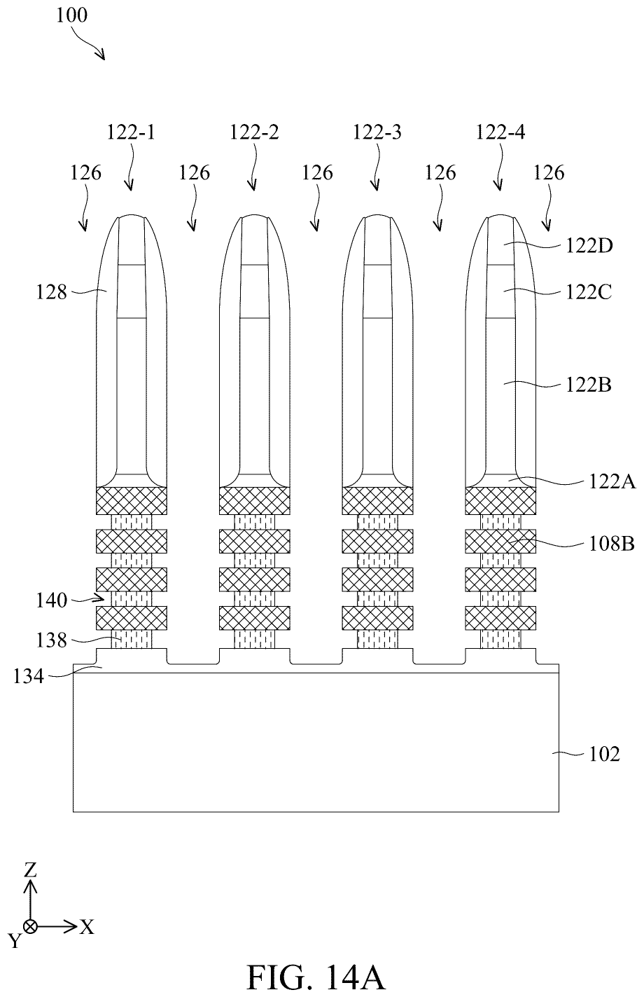

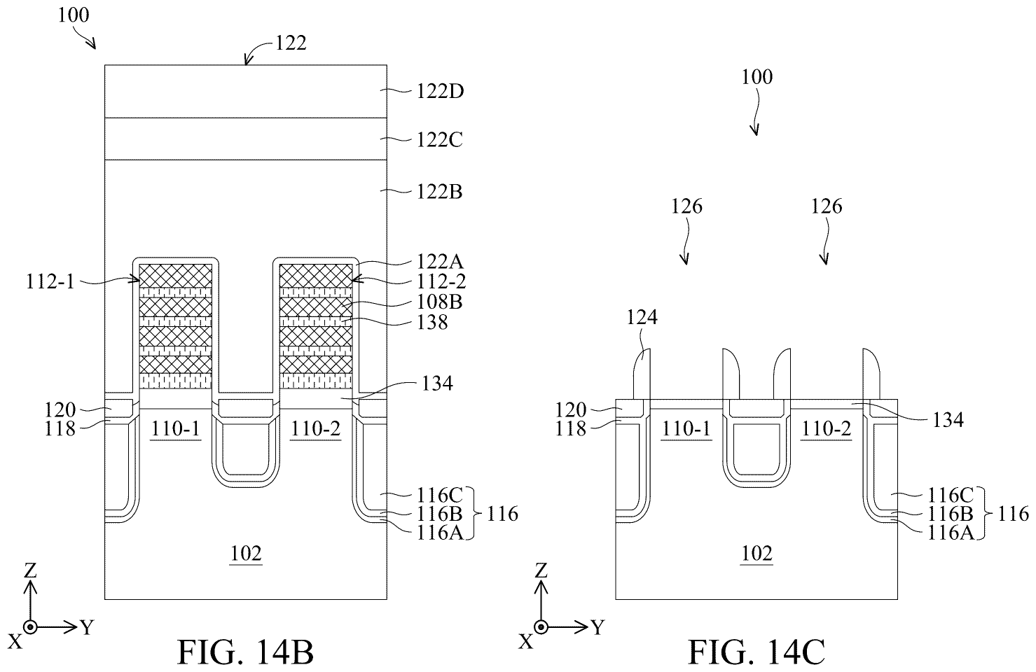

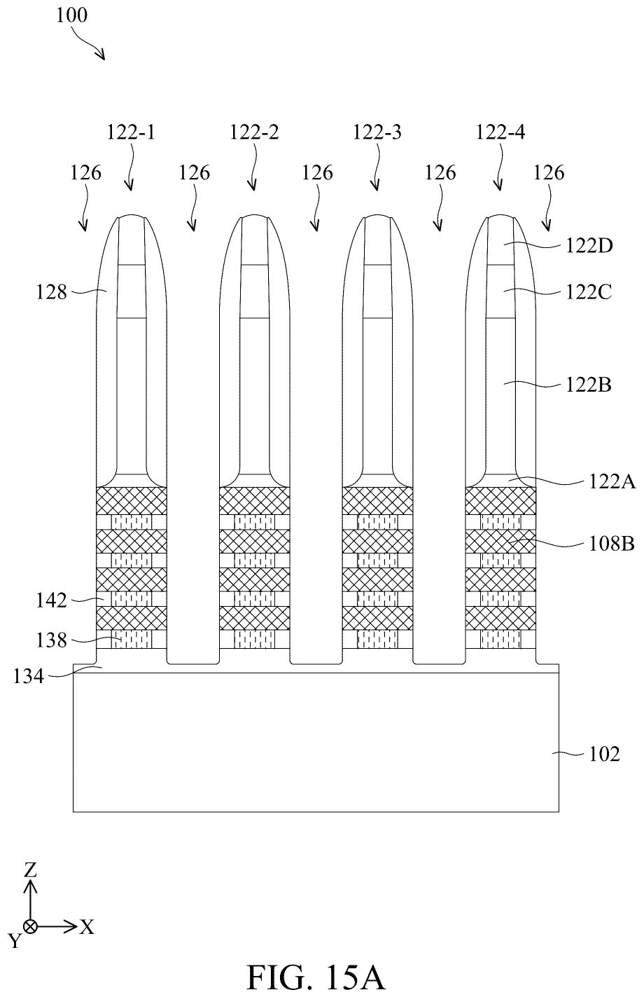

Referring to FIGS. 14A to 14C, side portions of the dielectric layers 138 are removed via a selective etching process. More specifically, the selective etching process is performed that selectively etches the side portions of the dielectric layers 138 below the gate spacers 128 through the source/drain trenches 126, with minimal (or no) etching of semiconductor layers 108B, the gate spacers 128, the dielectric layers 134, the hard mask layers 120, and the dielectric layers 134, such that gaps 140 are formed vertically between (the side portions of) the semiconductor layers 108B in the Z-direction as well as vertically between (the side portions of) the semiconductor layers 108B and the dielectric layers 134 in the Z-direction, and below the gate spacers 128, as shown in FIG. 14A. The etching process is configured to laterally etch (e.g., along the X-direction) the dielectric layers 138 below the gate spacers 128. The selective etching process is a dry etching process, a wet etching process, other suitable etching process, or combinations thereof.

As discussed above, the dielectric layers 138 and the dielectric material 116C include silicon oxide (SiO₂). However, as shown in FIG. 14C, due to the hard mask layers 120 are over the isolation features 116 to protect the dielectric material 116C of the isolation features 116, the side portions of the dielectric layers 138 are removed without damage or removal of the isolation features 116 (more specifically, the dielectric material 116C).

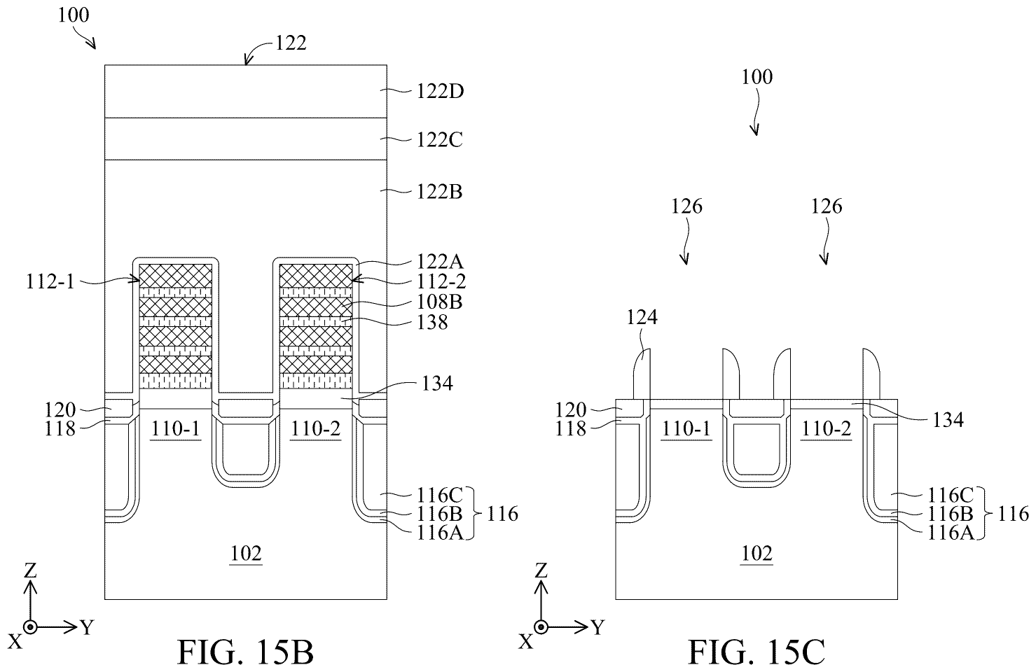

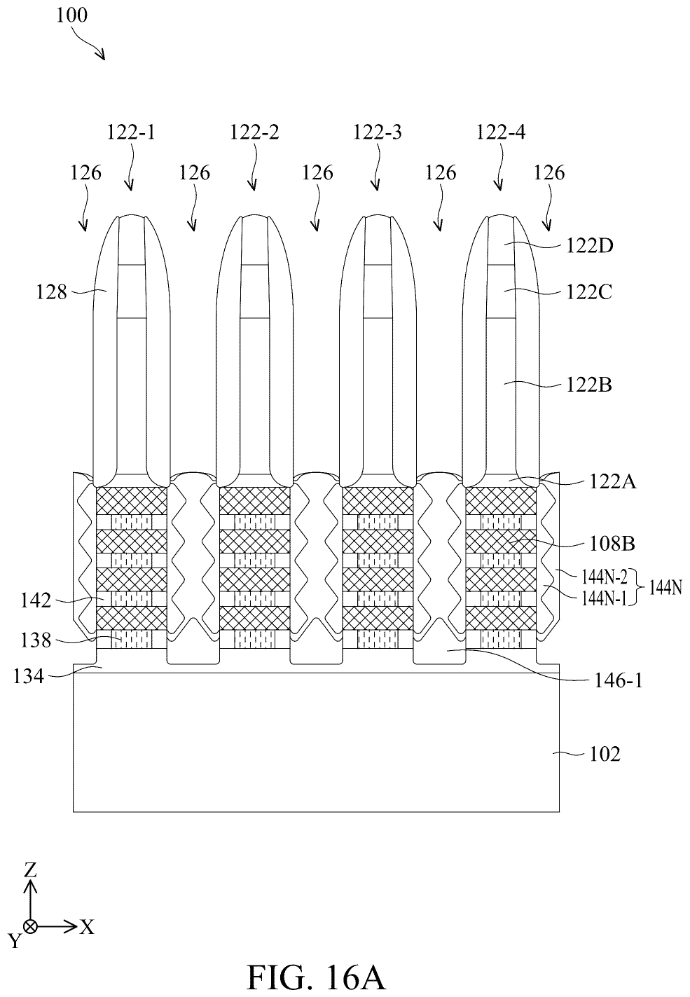

Referring to FIGS. 15A to 15C, inner spacers 142 are formed to fill the gaps 140. The inner spacers 142 are between the semiconductor layers 108B in the Z-direction and between the (bottommost) semiconductor layers 108B and the dielectric layers 134 direct under the gate spacers 128 in the Z-direction. In some embodiments, sidewalls of the inner spacers 142 are aligned to the sidewalls of the gate spacers 128 and the semiconductor layers 108B, as shown in FIG. 15A. In order to form the inner spacers 142, a deposition process forms a spacer layer into the source/drain trenches 126 and the gaps 140, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 126. The deposition process is configured to ensure that the spacer layer fills the gaps 140 between the semiconductor layers 108B as well as between the semiconductor layer 108B and the dielectric layers 134 under the gate spacers 128. An etching process is then performed that selectively etches the spacer layer to form inner spacers 142 (as shown in FIG. 15A) with minimal (to no) etching of the semiconductor layer 108B, the dielectric layers 134, the dummy gate structure 122, and the gate spacers 128, the hard mask layers 120, and the spacer layer 124.

The spacer layer (and thus inner spacers 142) includes a material that is different than a material of the semiconductor layers 108B and a material of the gate spacers 128 to achieve desired etching selectivity during the etching process. In some embodiments, the inner spacers 142 include a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)). In some embodiments, the inner spacers 142 include a low-k dielectric material, such as those described herein.

In some embodiments, the inner spacers 142 and the dielectric layers 134 have the same material. For examples, the inner spacers 142 and the dielectric layers 134 includes and are made of silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN). In these cases, the bottommost inner spacers 142 between the (bottommost) semiconductor layers 108B and the dielectric layers 134 and the dielectric layers 134 are merged together and the interface between them are not obvious. Therefore, the bottommost inner spacers 142 may be considered a portion of the dielectric layers 134 in the resultant device, in accordance with some embodiments.

Referring to FIGS. 16A to 16D, source/drain features 144N and 144P are formed in the source/drain trenches 126. More specifically, the source/drain features 144N and 144P are formed over the dielectric layers 134 and the substrate 102 in the source/drain trenches 126, so that the source/drain features 144N and 144P pass through the semiconductor layers 108B and are in the fins 112. The source/drain features 144N and 144P are also formed on opposite sides of the dummy gate structures 122 in the X-direction, as shown in FIGS. 16A and 16B. Furthermore, the source/drain features 144N and 144P are also disposed on opposite sides of the semiconductor layers 108B in the X-direction. The source/drain features 144N and 144P are connected to and in contact with the semiconductor layers 108B. More specifically, the source/drain features 144N and 144P are attached and electrically connected to the semiconductor layers 108B in the X-direction, as shown in FIGS. 16A and 16B.

In some embodiments, as shown in FIGS. 16A and 16B, the source/drain features 144N and 144P are also in contact with the inner spacers 142, but are electrically isolated from the inner spacers 142. In some aspects, the inner spacers 142 are disposed between the source/drain features 144N/144P and the dielectric layers 138 in the X-direction. In some aspects, the semiconductor layers 108B serve as channels to connect one source/drain feature 144N/144P to another source/drain feature 144N/144P. Therefore, the semiconductor layers 108 may also be referred to as channels, channel layers, channel members, or nanostructures.

One or more epitaxy processes may be employed to grow the source/drain features 144N and 144P. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 144N and 144P are grown from the semiconductor layers 108B rather than the substrate 102 due to the dielectric layers 134 cover the top surfaces of the substrate 102.

The source/drain features 144N and 144P may include any suitable semiconductor materials. For example, the source/drain features 144N used for n-type GAA transistors may include epitaxially-grown material selected from a group consisting of silicon phosphide (SiP), silicon carbide (SiC), silicon phosphoric carbide (SiPC), silicon arsenide (SiAs), silicon (Si), or a combination thereof. In some embodiments, the epitaxially-grown material of the source/drain features 144N may be doped with n-type dopants (such as phosphorus, arsenic, other n-type dopant, or combinations thereof). In some embodiments, the source/drain features 144N for n-type GAA transistors may respectively be referred to as n-type source/drain features.

The source/drain features 144P used for p-type GAA transistors may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 144P may be doped with p-type dopants (such as boron, indium, other p-type dopant, or a combination thereof). In some embodiments, the source/drain features 144P for p-type GAA transistors may respectively be referred to as p-type source/drain features.

The source/drain features 144N and 144P may also be referred to as source/drain, or source/drain regions. In some embodiments, source/drain feature(s) 144N/144P may refer to a source or a drain, individually or collectively dependent upon the context. The source/drain features 144N and 144P may be doped in-situ or ex-situ. One or more annealing processes may be performed to activate the dopants in the source/drain features 144N and 144P. The annealing processes may include rapid thermal annealing (RTA) and/or laser annealing processes.

In some embodiments, the source/drain features 144N are multi-layer structures and include liner layers 144N-1 on the semiconductor layers 108B and filling layers 144N-2 on the liner layers 144N-1, as shown in FIG. 16A. In some embodiments, the source/drain features 144P are multi-layer structures and include liner layers 144P-1 on the semiconductor layers 108B and filling layers 144P-2 on the liner layers 144P-1, as shown in FIG. 16B. In some embodiments, the dopant concentrations of the liner layers 144N-1 and 144P-1 are respectively less than the dopant concentrations of the filling layers 144N-2 and 144P-2.

As discussed above, the source/drain features 144N and 144P are grown from the semiconductor layers 108B rather than the substrate 102 due to the dielectric layers 134 cover the top surfaces of the substrate 102. Therefore, the formation of the source/drain features 144N and 144P can be controlled to partially fill the 126. As such, air gaps 146-1 and 146-2 are respectively formed under the source/drain features 144N and 144P. More specifically, the air gaps 146-1 are formed between the source/drain features 144N and the dielectric layers 134 in the Z-direction, and the air gaps 146-2 are formed between the source/drain features 144P and the dielectric layers 134 in the Z-direction, as shown in FIGS. 16A to 16D.

In some embodiments, the air gaps 146-1 under the source/drain features 144N are larger than the air gaps 146-2 under the source/drain features 144P, as shown in FIGS. 16A, 16B, and 16D. Furthermore, highest points of the air gaps 146-1 under the source/drain features 144N are higher than highest points of the air gaps 146-2 under the source/drain features 144P, as shown in FIGS. 16A, 16B, and 16D. It is noted that the source/drain features 144N are separated from the dielectric layers 134 by the air gaps 146-1, as shown in FIGS. 16A and 16D. In contrast, as shown in FIGS. 16B and 16D, the source/drain features 144P are in contact with the dielectric layers 134 although the air gaps 146-2 are between the source/drain features 144P and the dielectric layers 134.

In the Y-Z cross-sectional view of the workpiece 100 shown in FIG. 16D, the air gaps 146-1 have rectangular shapes, and the air gaps 146-2 have semi-oval shapes. In the X-Z cross-sectional view of the workpiece 100 shown in FIG. 16A, the source/drain features 144N have bottom surfaces with acute angles, such that the air gaps 146-1 under the source/drain features 144N have top surfaces with acute angles. In the X-Z cross-sectional view of the workpiece 100 shown in FIG. 16B, the source/drain features 144P have concave bottom surfaces, such that the air gaps 146-2 under the source/drain features 144P have convex top surfaces.

Therefore, the source/drain features 144P have larger volumes to have better strain for improved hole mobility. It should be also noted that the source/drain features 144N and 144P are separated from the substrate 102 (more specifically, the base fins 110-1 and 110-2) by the dielectric layers 134. As such, it prevents the leakage current of the resultant transistors from one source/drain feature 144N/144P to another source/drain feature 144N/144P through the substrate 102 (more specifically, the base fins 110-1 and 110-2), thereby improving the performances of the resultant transistors. Furthermore, the air gaps 146-1 and 146-2 under the source/drain features 144N and 144P have low dielectric constant (low-k, k=1). Therefore, the parasitic capacitances between the source/drain features 144N/144P and the substrate 102 are reduced, thereby improving the performances of the resultant transistors.

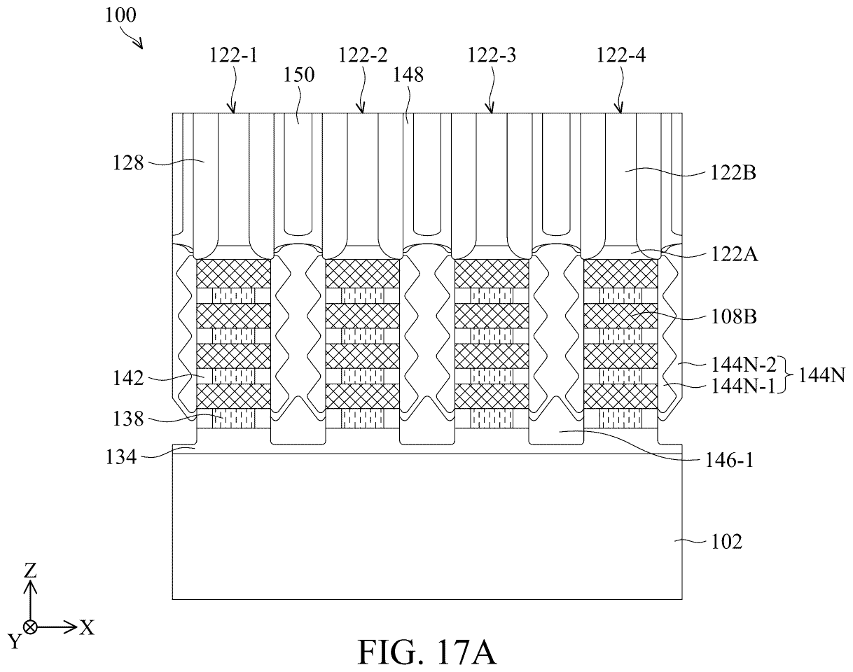

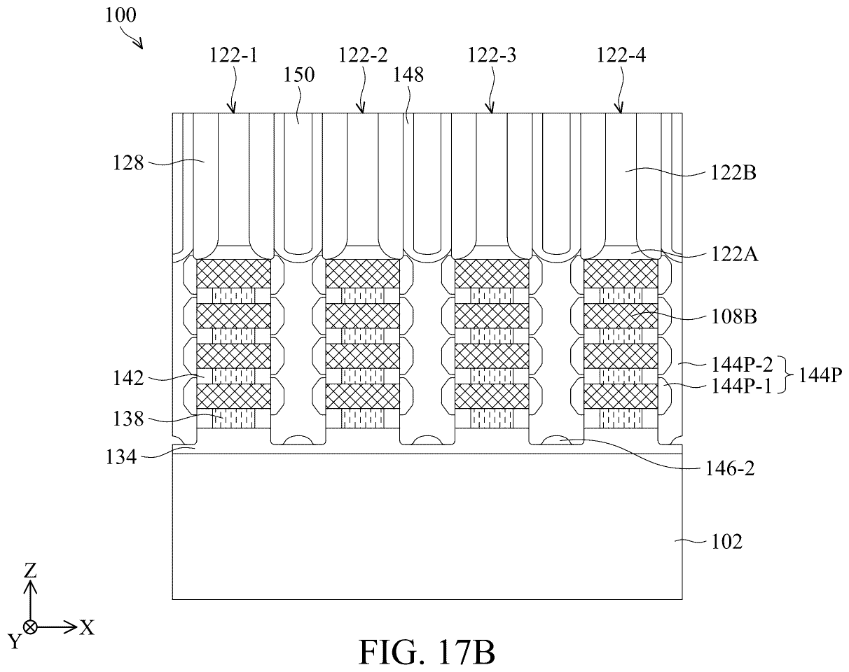

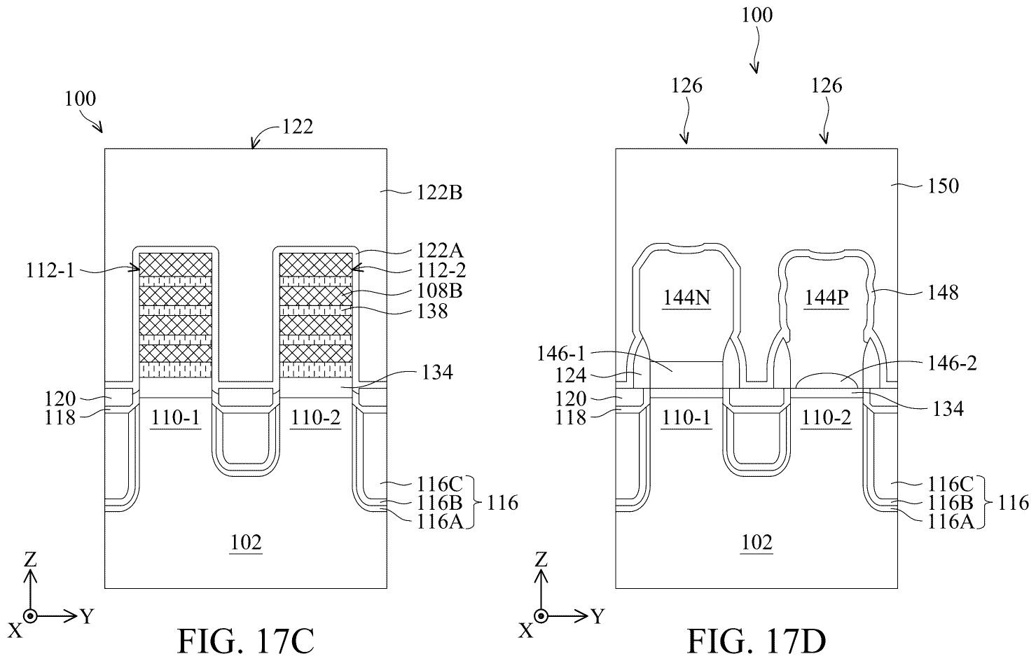

Referring to FIGS. 17A to 17D, a contact etch stop layer (CESL) 148 over the source/drain features 144N and 144P and an interlayer dielectric (ILD) layer 150 over the CESL 148 are formed to fill the space between the gate spacers 128 and in the source/drain trenches 126. Specifically, the CESL 148 is conformally formed on the sidewalls of the gate spacers 128, the spacer layer 124, and the source/drain features 144N and 144P, over the top surfaces of the source/drain features 144N and 144P and the hard mask layers 120, as shown in FIGS. 17A to 17D.

The ILD layer 150 is then formed over the CESL 148 to fill remaining spaces between (or inside) the CESL 148, between the gate spacers 128 and in the source/drain trenches 126. The CESL 148 includes a material that is different than ILD layer 150.

The CESL 148 may include La₂O₃, Al₂O₃, SiOCN, SiOC, SiCN, SiO₂, SiC, ZnO, ZIN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 150 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 150 may be formed by PECVD (plasma enhanced CVD), FCVD (flowable CVD), or other suitable methods.

Subsequent to the deposition of the CESL 148 and the ILD layer 150, a CMP process and/or other planarization process is performed on the CESL 148, the ILD layer 150, the gate spacers 128, and the hard mask layers 122C and 122D until the top surfaces of the dummy gate electrodes 122B are exposed. Therefore, the heights of the gate spacers 128 and the dummy gate structures 122 are reduced. Furthermore, the top surfaces of the gate spacers 128, the dummy gate structures 122 (the dummy gate electrodes 122B), the CESL 148, and the ILD layer 150 are substantially level with each other (i.e., coplanar), as shown in FIGS. 17A and 17B.

In some embodiments, the ILD layer 150 is recessed to a level below the top surface of the dummy gate electrodes 122B, and then an ILD protection layer is formed over the ILD layer 150 to protect the ILD layer 150 from subsequent etching processes. As such, the ILD layer 150 is surrounded by the CESL 148 and the ILD protection layer. In some embodiments, the ILD protection layer includes a material that is the same as or similar to that in the CESL 148. In some other embodiments, the ILD protection layer includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, or other suitable methods.

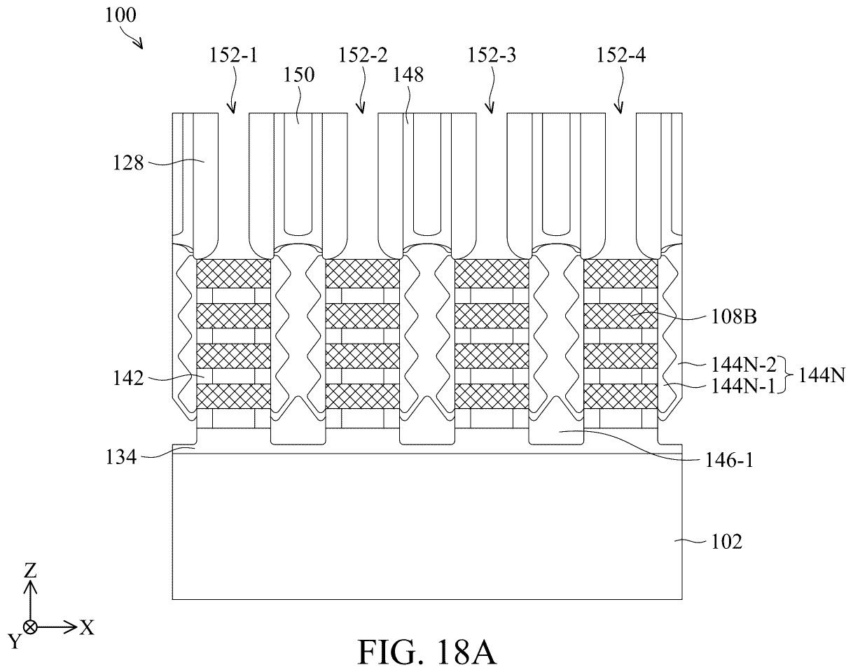

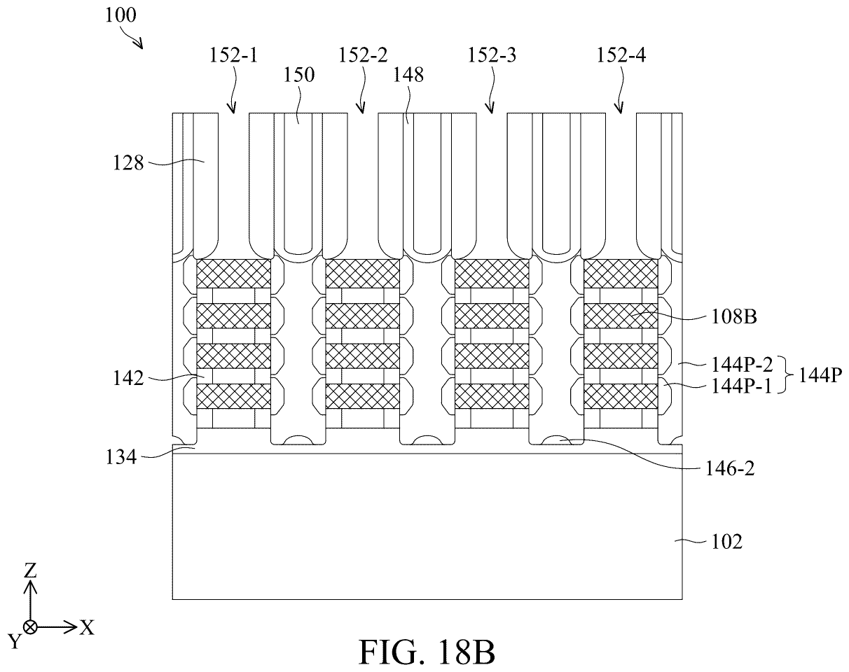

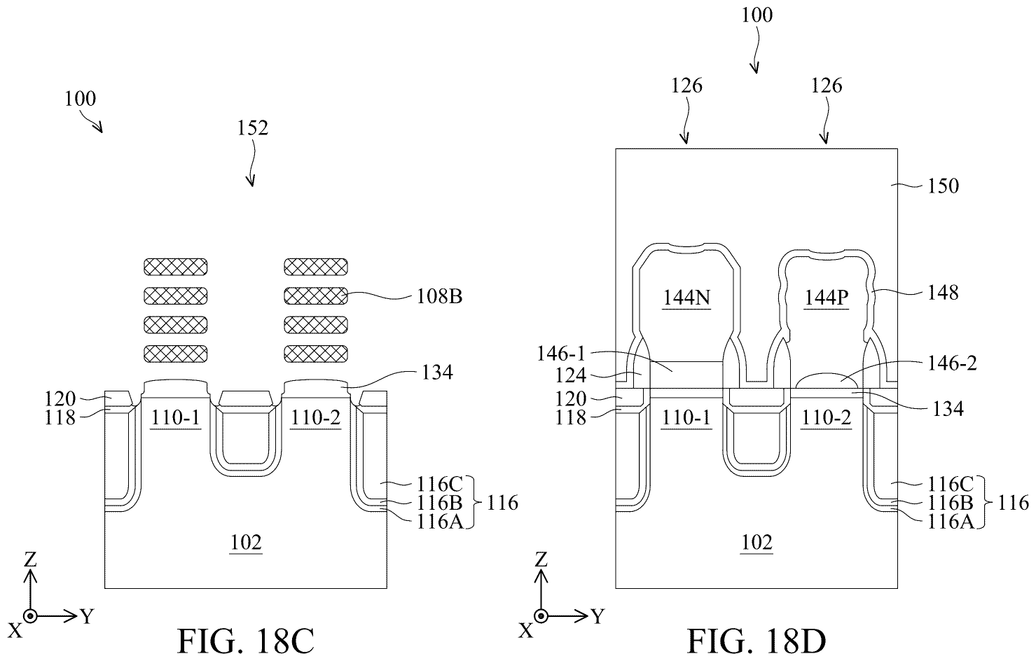

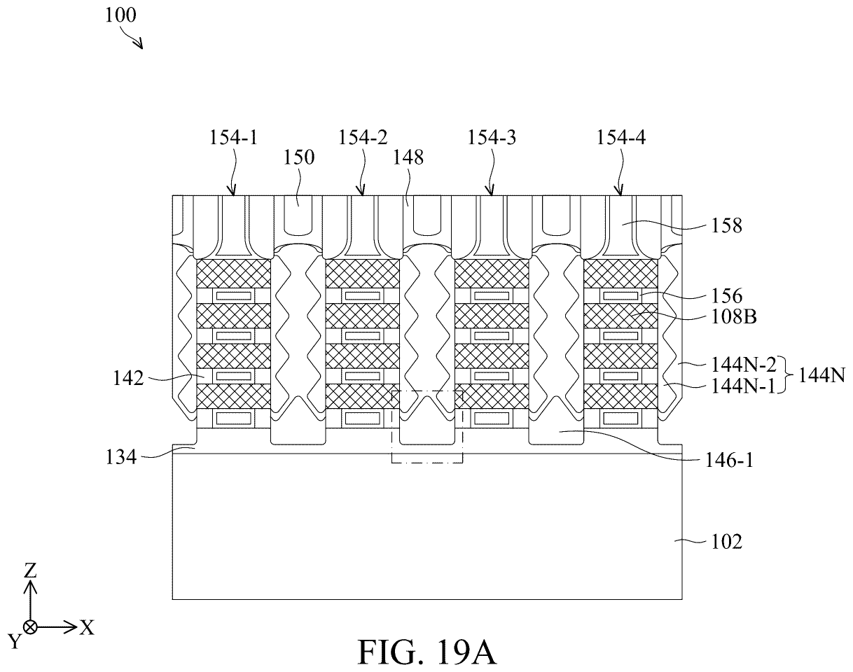

Referring to FIGS. 18A to 18D, the dummy gate structures 122 are selectively removed through any suitable lithography and etching processes to form gate trenches 152 (including gate trenches 152-1 to 152-4). In some embodiments, the lithography process may include forming a photoresist layer (resist), exposing the resist to a pattern, performing a post-exposure bake process, and developing the resist to form a masking element, which exposes a region including the dummy gate structures 122. Then, the dummy gate structures 122 are selectively etched through the masking element. The gate spacers 128 may be used as the masking element or a part thereof. Etch selectivity may be achieved by selecting the appropriate etching chemicals, and the dummy gate structures 122 may be removed without substantially affecting the CESL 148 and the ILD layer 150. The removal of the dummy gate structures 122 creates the gate trenches 152-1 to 152-4, in which the gate trenches 152-1 to 152-4 expose the top surfaces of the fins 112 (specifically, the top surfaces of the topmost semiconductor layers 108B).

Still referring to FIGS. 18A to 18D, the dielectric layers 138 are selectively removed through the gate trenches 152, using a wet or dry etching process for example, so that middle portions of the semiconductor layers 108B are exposed in the gate trenches 152 to form nanostructures stacked over each other, which serving as channels, channel layers, or channel members for resultant transistors. In some embodiments, the hard mask layers 120 and the dielectric layers 134 are also exposed in the gate trenches 152, as shown in FIG. 17B. As discussed above, the dielectric layers 138 and the dielectric material 116C include silicon oxide (SiO₂). However, as shown in FIG. 18C, due to the hard mask layers 120 are over the isolation features 116 to protect the dielectric material 116C of the isolation features 116, the dielectric layers 138 are removed without damage or removal of the isolation features 116 (more specifically, the dielectric material 116C).

As such, the semiconductor layers 108B may be referred to as nanostructures. Specifically, the semiconductor layers 108B are stacked over each other in the Z-direction. Such a process may also be referred to as a release process, a channel release process, a wire release process, a nanowire release process, a nanosheet release process, a nanowire formation process, a nanosheet formation process, or a wire formation process.

In some embodiments, the removal of the dielectric layers 138 causes the exposed semiconductor layers 108B (the nanostructures) to be spaced apart from each other in the vertical direction (e.g., in the Z-direction). The exposed semiconductor layers 108B (the nanostructures) extend longitudinally in the horizontal direction (e.g., in the X-direction). As shown in FIGS. 18A and 18B, sidewalls of the inner spacers 142 are also exposed in the gate trenches 152. Furthermore, each of the semiconductor layers 108B connects one source/drain feature 144N/144P to another source/drain feature 144N/144P (e.g., shown in FIGS. 18A and 18B).

In some embodiments, due to the high selectivity between the semiconductor layers 108B and the dielectric layers 138 (e.g., the semiconductor layers 108B are made of silicon (Si) and the dielectric layers 138 are made of silicon oxide (SiO₂)), the dielectric layers 138 can be removed damage or removal of the semiconductor layers 108B (the nanostructures). Therefore, the semiconductor layers 108B (the nanostructures) remain rectangular shapes in the X-Z cross-sectional views of the workpiece 100 shown in FIGS. 18A and 18C rather than the semiconductor layers 108B (the nanostructures) with thinner middle portions (e.g., the dumbbell-like shape)

Referring to FIGS. 19A to 19D, gate structures 154 (including gate structures 154-1 to 154-4) are formed in the gate trenches 152 to wrap around the exposed semiconductor layers 108B (nanostructures). As such, the gate structures 154 replace the dummy gate structures 122 and the dielectric layers 138. In some embodiments, the gate structures 154 extend in the Y-direction, as shown in FIG. 19C. As shown in FIGS. 19A and 149B, the source/drain features 144N/144P are formed on opposite sides of the gate structures 154 in the X-direction. The gate structures 154 each includes a gate dielectric layer 156 and a gate electrode layer 158 over the gate dielectric layer 156. In some embodiments, the gate dielectric layers 156 are formed to wrap around the semiconductor layers 108B (nanostructures) in the gate trenches 152. Additionally, the gate dielectric layers 156 also formed on the sidewalls of the inner spacers 142 and the gate spacers 128.

The gate dielectric layers 156 may include a dielectric material having a dielectric constant greater than a dielectric constant of SiO₂, which is approximately 3.9. For example, the gate dielectric layers 156 may include hafnium oxide (HfO₂), which has a dielectric constant in a range from about 18 to about 40. Alternatively, the gate dielectric layers 156 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 156 may be formed by ALD, PVD, CVD, oxidation, and/or other suitable methods.

In some embodiments, the gate structures 154 each may further include interfacial layer formed to wrap around the exposed semiconductor layers 108B before the formation of the gate dielectric layers 156, so that the gate dielectric layers 156 are separated from semiconductor layers 108B by the interfacial layer. In some embodiments, the interfacial layer may include a dielectric material such as silicon oxide (SiO₂), HfSiO, or silicon oxynitride (SiON). The interfacial layer may be formed by chemical oxidation, thermal oxidation, ALD, CVD, and/or other suitable method.

The gate electrode layers 158 are formed to fill the remaining spaces of the gate trenches 152, and over the gate dielectric layers 156 in such a way that the gate electrode layers 158 wrap around the semiconductor layers 108B, the gate dielectric layers 156, and the interfacial layers (if present). The gate electrode layers 158 each may include a single layer or alternatively a multi-layer structure. In some embodiments, the gate electrode layers 158 each may include a capping layer, a barrier layer, work function metal layers, and a fill material.

The capping layer may be formed adjacent to the gate dielectric layers 156 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The gate electrode layers 158 may each has single or multiple work function metal materials. In some embodiments, the gate electrode layers 158 may each has n-type work function metal layers for n-type GAA transistors and p-type work function metal layers for p-type GAA transistors. More specifically, the gate electrode layers 158 may each has n-type work function metal layers between the source/drain features 144N with n-type dopant for n-type GAA transistors and p-type work function metal layers between the source/drain features 144P with p-type dopant for p-type GAA transistors, in accordance with some embodiments of the present disclosure.

The n-type work function metal layer may be formed adjacent to the barrier layer. In an embodiment, the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

The p-type work function metal layer may be formed adjacent to the n-type work function metal layer. In an embodiment, the p-type work function metal layer may be a material such as TiN, TaN, Ru, Mo, Al, WN, ZrSi₂, MoSi₂, TaSi₂, NiSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-type work function metal layer may be deposited using a deposition process such as ALD, CVD, or the like, although any suitable deposition process may be used.

As shown in FIGS. 19A to 19C, after the formation of the gate dielectric layers 156 and the gate electrode layers 158 for the gate structures 154, a planarization process (e.g., a CMP process) is performed on the gate dielectric layer 156, the gate electrode layers 158, the gate spacers 128, the CESL 148, and the ILD layer 150, such that the heights of the gate dielectric layer 154, the gate electrode layers 156, the gate spacers 128, the CESL 148, and the ILD layer 150 are reduced. Furthermore, top surfaces of the gate structures 154 (the gate dielectric layer 156 and the gate electrode layers 158), the gate spacers 128, the CESL 148, and the ILD layer 150 are substantially level with each other (i.e., coplanar), as shown in FIGS. 19 and 19B.

As shown in FIGS. 19A and 19B, the gate structures 154 are also formed over and in contact with the dielectric layers 134 in the Z-direction. In some aspects, the dielectric layers 134 are formed under the gate structures 154. In other words, the dielectric layers 134 are also between the gate structures 154 and the substrate 102. The gate structures 154 are separated from the substrate 102 by the dielectric layers 134, such that the parasitic capacitance between the gate structures 154 and the substrate 102 are reduced due to the gate structures 154 and the substrate 102 are separated, thereby improving the performance of the GAA transistors.

As shown in FIGS. 19A to 19D, top surfaces of the dielectric layers 134 in contact with the gate structures 152 are higher than top surfaces of the dielectric layers 134 exposed in the air gaps 146-1 and 146-2. In other words, thicknesses of the dielectric layers 134 in contact with the gate structures 152 are greater than thicknesses of the dielectric layers 134 exposed in the air gaps 146-1 and 146-2. The workpiece (the semiconductor structure) 100 with transistors (e.g., GAA transistors) are completed after the formation of the gate structures 154. The transistors are formed with the dielectric layers 134 continuously extending in the X-direction under the gate structures 152 and the source/drain features 144N/144P, such that the parasitic capacitance of the resultant transistors are reduced. Furthermore, such structure is more applicable to the existing processes for GAA transistors.

FIGS. 20A and 21A are partial enlarged cross-sectional views of the workpiece 100 at the fabrication stage in a dashed box of FIG. 19A, in accordance with some alternative embodiments of the present disclosure. FIGS. 20B and 21B are partial enlarged cross-sectional views of the workpiece 100 at the fabrication stage in the dashed box of FIG. 19B, in accordance with some alternative embodiments of the present disclosure. Referring back to FIGS. 19A to 19D, the top surfaces of the dielectric layers 134 under the source/drain features 144N/144P are planar (i.e., the planar top surfaces). In some aspects, bottom surfaces of the air gaps 146-1 and 146-2 are planar (i.e., the planar bottom surfaces), as shown in FIGS. 19A to 19D.

In some embodiments, the top surfaces of the dielectric layers 134 under the source/drain features 144N/144P are non-planer. As shown in FIGS. 20A and 20B, the bottom surfaces of the dielectric layers 134 are convex. In other words, the dielectric layers 134 have convex bottom surfaces under the source/drain features 144N/144P. Therefore, the bottom surfaces of the air gaps 146-1 and 146-2 are concave (i.e., the concave bottom surfaces), as shown in FIGS. 20A and 20B. As shown in FIGS. 21A and 21B, the bottom surfaces of the dielectric layers 134 are concave. In other words, the dielectric layers 134 have concave bottom surfaces under the source/drain features 144N/144P. Therefore, the bottom surfaces of the air gaps 146-1 and 146-2 are convex (i.e., the convex bottom surfaces), as shown in FIGS. 21A and 21B.

FIGS. 22A, 22B, 22C, and 22D are cross-sectional views of the workpiece 100 at various fabrication stages along the line A-A′, B-B′, C-C′, and D-D′ of FIG. 5, respectively, in accordance with some alternative embodiments of the present disclosure. Referring back to FIGS. 8A to 8D, the source/drain trenches 126 are formed with minimal (or no) etching of the substrate 102. Therefore, referring back to FIGS. 19A to 19D, the bottom surfaces of the dielectric layers 134 are planar (i.e., the planar bottom surfaces). Furthermore, the bottom surfaces of the dielectric layers 134 are higher than the top surfaces of the isolation features 116 in the Y-Z cross-sectional view of the workpiece 100, as shown in FIG. 19D.

In some embodiments, the substrate 102 are etched during the formation of the source/drain trenches 126, such that the source/drain trenches 126 have extending portions deep extended into the substrate 102. As such, the bottom surfaces of the dielectric layers 134 are non-planar, as shown in FIGS. 22A to 22D. Furthermore, the bottom surfaces of the dielectric layers 134 are lower than the top surfaces of the isolation features 116 in the Y-Z cross-sectional view of the workpiece 100, as shown in FIG. 22D. The dielectric layers 134 with such extending portions deep into the substrate 102 under the source/drain features 144N/144P shown in FIGS. 22A and 22B further reduce the leakage current of the resultant transistors, thereby improving the performance of the GAA transistors in the workpiece 100.

The embodiments disclosed herein relate to semiconductor structures and their manufacturing methods, and more particularly to methods and semiconductor structures including continuous dielectric layers under gate structures and source/drain features, and air gaps under the source/drain features. Furthermore, the present embodiments provide one or more of the following advantages. The dielectric layers under the gate structures and the source/drain features reduce the parasitic capacitance between the gate structures and the substrate and the parasitic capacitance between the source/drain features and the substrate, thereby improving the performance of the resultant transistors. The dielectric layers under the gate structures and the source/drain features also reduce the leakage current of the resultant transistors, thereby improving the performance of the resultant transistors. The air gaps under the source/drain features have low dielectric constant for reducing the parasitic capacitances between the source/drain features and the substrate 102, thereby improving the performances of the resultant transistors.

Thus, one of the embodiments of the present disclosure describes a method for manufacturing a semiconductor structure that includes forming fins over a substrate. Each of the fins includes first semiconductor layers and second semiconductor layers alternating stacked, and a third semiconductor layer under the first semiconductor layers and the second semiconductor layers. The method further includes forming a dummy gate structure over the fins, forming source/drain trenches in the fins and on opposite sides of the dummy gate structures, removing the third semiconductor layers, forming first dielectric layers under the first semiconductor layers and the second semiconductor layers and in the source/drain trenches, replacing the first semiconductor layers with second dielectric layers, forming source/drain features in the source/drain trenches and on opposite sides of the dummy gate structure, forming air gaps between the source/drain features and the first dielectric layers, and replacing the dummy gate structure and the second dielectric layers with a gate structure wrapping around the second semiconductor layers and over the first dielectric layers.

In another of the embodiments, discussed is a method for manufacturing a semiconductor structure including forming fins over a substrate. Each of the fins includes first semiconductor layers and second semiconductor layers alternating stacked in a Z-direction, and a third semiconductor layer under the first semiconductor layers and the second semiconductor layers. The method further includes forming a dummy gate structure extending in a Y-direction and over the fins, forming source/drain trenches in the fins and on opposite sides of the dummy gate structures in an X-direction, removing the third semiconductor layers to form gaps, forming dielectric layers in the gaps and over the substrate exposed in the source/drain trenches, removing the first semiconductor layers, forming oxide layers between the second semiconductor layers in the Z-direction and between second semiconductor layers and the dielectric layers in the Z-direction, forming source/drain features in the source/drain trenches and on opposite sides of the dummy gate structure in the X-direction, and replacing the dummy gate structure and the oxide layers with a gate structure wrapping around the second semiconductor layers. Air gaps are formed between the source/drain features and the dielectric layers in the Z-direction. The gate structure is over and in contact with the dielectric layers.

In yet another of the embodiments, discussed is a semiconductor structure including a substrate, semiconductor layers, source/drain features, a gate structure, dielectric layers, and air gaps. The semiconductor layers are over the substrate and spaced apart from each other in a Z-direction. The source/drain features are attached to the semiconductor layers in an X-direction. The gate structure extends in a Y-direction and wraps around the semiconductor layers. The dielectric layers are under the source/drain features and the gate structure. The gate structure is in contact with the dielectric layers in the Z-direction. The air gaps are between the source/drain features and the dielectric layers in the Z-direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming fins over a substrate, wherein each of the fins comprises first semiconductor layers and second semiconductor layers alternating stacked, and a third semiconductor layer under the first semiconductor layers and the second semiconductor layers;
forming a dummy gate structure over the fins;
forming source/drain trenches in the fins and on opposite sides of the dummy gate structures;
removing the third semiconductor layers;
forming first dielectric layers under the first semiconductor layers and the second semiconductor layers and in the source/drain trenches;
replacing the first semiconductor layers with second dielectric layers;
forming source/drain features in the source/drain trenches and on opposite sides of the dummy gate structure;
forming air gaps between the source/drain features and the first dielectric layers; and
replacing the dummy gate structure and the second dielectric layers with a gate structure wrapping around the second semiconductor layers and over the first dielectric layers.

2. The method of claim 1, further comprising:
removing side portions of the second dielectric layers to form gaps:
forming inner spacers in the gaps, wherein the inner spacers are between the second semiconductor layers and between the second semiconductor layers and the first dielectric layers.

3. The method of claim 2, wherein the inner spacers and the first dielectric layers have the same material.

4. The method of claim 1,
wherein each of the fins further comprises a fourth semiconductor layer over the third semiconductor layers and under the first semiconductor layers and the second semiconductor layers,
wherein the second semiconductor layers and the fourth semiconductor layers are formed of silicon,
wherein the first semiconductor layers and the third semiconductor layers are formed of silicon germanium with different germanium concentrations,
wherein the method further comprises:
replacing the first semiconductor layers and the fourth semiconductor layer with second dielectric layers.

5. The method of claim 1, wherein replacing the first semiconductor layers with the second dielectric layers comprises:
removing the first semiconductor layers through the source/drain trenches; and
forming the second dielectric layers between the second semiconductor layers and between the second semiconductor layers and the first dielectric layers.

6. The method of claim 1, wherein top surfaces of the first dielectric layers in contact with the gate structure are higher than top surfaces of the first dielectric layers exposed in the air gaps.

7. The method of claim 1, wherein the source/drain features comprise:
first source/drain features with n-type dopants; and
second source/drain features with p-type dopants,
wherein the air gaps under the first source/drain features are larger than the air gaps under the second source/drain features.

8. The method of claim 7, wherein the first source/drain features are in contact with the first dielectric layer.

9. The method of claim 7, wherein the air gaps under the first source/drain features have top surfaces with acute angles.

10. The method of claim 7, wherein the air gaps under the second source/drain features have convex top surfaces.

11. A method for manufacturing a semiconductor structure, comprising:
forming fins over a substrate, wherein each of the fins comprises first semiconductor layers and second semiconductor layers alternating stacked in a Z-direction, and a third semiconductor layer under the first semiconductor layers and the second semiconductor layers;
forming a dummy gate structure extending in a Y-direction and over the fins;
forming source/drain trenches in the fins and on opposite sides of the dummy gate structures in an X-direction;
removing the third semiconductor layers to form gaps;
forming dielectric layers in the gaps and over the substrate exposed in the source/drain trenches;
removing the first semiconductor layers;
forming oxide layers between the second semiconductor layers in the Z-direction, and between second semiconductor layers and the dielectric layers in the Z-direction;
forming source/drain features in the source/drain trenches and on opposite sides of the dummy gate structure in the X-direction, wherein air gaps are formed between the source/drain features and the dielectric layers in the Z-direction; and
replacing the dummy gate structure and the oxide layers with a gate structure wrapping around the second semiconductor layers, wherein the gate structure is over and in contact with the dielectric layers.

12. The method of claim 11, wherein the dielectric layers comprise Si₃N₄, SiC, SiOC, SION, SiCN, SiOCN, or a combination thereof.

13. The method of claim 11, wherein the source/drain features comprise:
first source/drain features with n-type dopants; and
second source/drain features with p-type dopants,
wherein the first source/drain features are separated from the dielectric layers,
wherein the second source/drain features are in contact with the dielectric layers.

14. The method of claim 13, wherein the first source/drain features have bottom surfaces with acute angles.

15. The method of claim 13, wherein the second source/drain features have concave bottom surfaces.

16. The method of claim 11, wherein the dielectric layers have convex bottom surfaces under the source/drain features.

17. The method of claim 11, wherein the dielectric layers have concave bottom surfaces under the source/drain features.

18. A semiconductor structure, comprising:
a substrate;
semiconductor layers over the substrate and spaced apart from each other in a Z-direction;
source/drain features attached to the semiconductor layers in an X-direction;
a gate structure extending in a Y-direction and wrapping around the semiconductor layers;
dielectric layers under the source/drain features and the gate structure, wherein the gate structure is in contact with the dielectric layers in the Z-direction; and
air gaps between the source/drain features and the dielectric layers in the Z-direction.

19. The semiconductor structure of claim 18, wherein the source/drain features comprise:
first source/drain features with n-type dopants; and
second source/drain features with p-type dopants,
wherein highest points of the air gaps under the first source/drain features are higher than highest points of the air gaps under the second source/drain features.

20. The semiconductor structure of claim 18, wherein the dielectric layers have non-planer top surfaces under the source/drain features.
